(19) United States
(12) Patent Application Publication
(10) Pub. No.: US 2008/0101113 A1
(43) Pub. Date: May 1, 2008

(54) Memory device and method of manufacturing the same

(75) Inventor: Jin-Jun Park, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/906,680

(22) Filed: Oct. 3, 2007

(30) Foreign Application Priority Data
Oct. 26, 2006 (KR) 10-2006-0104276

(51) Int. Cl. G11C 11/52; H01L 21/82

(52) U.S. Cl. 365/166; 438/128; 257/E21.606

(57) ABSTRACT

There are provided a memory device capable of writing and reading data at a low voltage and a method of manufacturing the same. The memory device comprises: a bit line formed in one direction; a plurality of word lines provided crosswise above the bit line, the word lines formed in parallel with a vacant space formed therebetween; a flip electrode electrically connected to the bit line, formed over one of the word lines above the bit line to pass the vacant space, and configured to be bent in one direction with respect to the plurality of word lines by electric fields induced between the plurality of word lines; and a contact part protruding from a lower end of the flip electrode concentrates charges induced by the flip electrode in response to charges applied by the word line to selectively bring the word line into contact with the flip electrode.

### CROSS-REFERENCE TO RELATED APPLICATION

This application claims priority under 35 U.S.C. §119 to Korean Patent Application No. 10-2006-0104276, filed Oct. 26, 2006, the disclosure of which is hereby incorporated herein by reference in its entirety.

### BACKGROUND OF THE INVENTION

1. Technical Field

The present invention relates to a memory device and a method of manufacturing the same, and more particularly to a memory device capable of reducing power consumption by writing and reading data in a low voltage state and a method of manufacturing the same.

2. Discussion of Related Art

In general, memory devices used to store data are classified into volatile memory devices and nonvolatile memory devices. In memory devices, while the volatile memories including a dynamic random access memory (DRAM) and a static random access memory (SRAM) can quickly input and output data, but stored data is lost if the power supply is interrupted, the nonvolatile memory semiconductor devices including an erasable programmable read only memory (EPROM) and an electrically erasable programmable read only memory (EEPROM) slowly input and output data, but maintain stored data even if the power supply is interrupted.

Meanwhile, the conventional memory devices basically have employed a metal oxide semiconductor field effect transistor (MOSFET) based on the metal oxide semiconductor (MOS) technology. For example, a stack gate type transistor memory device having a structure stacked on a semiconductor substrate of a silicon material and a trench gate type transistor memory device having a structure buried in the interior of a semiconductor substrate have been developed. However, since the MOSFET should have a channel with a size having a predetermined width and length or more in order to prevent a single channel effect, and the thickness of a gate insulating layer formed between the gate electrode on a channel and the semiconductor substrate should be extremely thin, it is difficult to realize a memory device having a nano scale ultra-minute structure.

For this reason, a memory device having a structure capable of replacing the MOSFET has been actively researched and developed. Recently, the micro electro-mechanical system (MEMS) technology and the nano electromechanical system (NEMS) technology developed by applying the semiconductor technology have been suggested. Among them, a memory device employing a carbon nano tube is disclosed in U.S. Patent Publication No. 2004/0181630 entitled “Devices having horizontally-disposed nanofabric articles and methods of making”.

Hereinafter, a conventional memory device will be described with reference to accompanying drawings.

FIG. 1 is a cross-sectional view illustrating a conventional memory device.

As illustrated in FIG. 1, the conventional memory device includes a lower electrode 112 and an upper electrode 168 formed in one direction in parallel to each other and separated from each other by a predetermined interval, and a nano tube piece 154 separated from the lower electrode 112 or the upper electrode 168 so as to pass between the lower electrode 112 and the upper electrode 168 and storing data when it is separated from or makes contact with the lower electrode 112 or the upper electrode 168.

Here, the lower electrode 112 is buried in a cavity formed in a first interlayer insulating layer 176 on a semiconductor substrate. For example, the lower electrode 112 is formed of a conductive metal or a semiconductor material.

The upper electrode 168 is formed over the lower electrode 112, and designed to be separated from the lower electrode 112 with a vacant space disposed therebetween. Then, the upper electrode 168 is supported by a second interlayer insulating layer (not shown) formed on the first interlayer insulating layer 176.

The nano tube piece 154 passes the center of the vacant space formed between the lower electrode 112 and the upper electrode 168 and makes contact with the lower electrode 112 or the upper electrode 168 under a predetermined condition. For example, the nano tube piece 154 is seated on an upper portion of a nitride layer formed on the first interlayer insulating layer 176 at the periphery of the lower electrode 112 and is floated by a predetermined height from the lower electrode 112. Further, the nano tube piece 154 is bent toward the direction of the lower electrode 112 or the upper electrode 168 to which a charge opposite to the type of the charge applied to the nano tube piece 154 is applied and makes contact with the lower electrode 112 or the upper electrode 168. If the nano tube piece 154 is to make contact with the lower electrode 112, a same charge as the charge applied to the nano tube piece 154 is applied to the upper electrode 168 opposite to the lower electrode 112. Then, a predetermined charge should be applied to the lower electrode 112 in order to bring the nano tube piece 154 into contact with the lower electrode 112 continuously. Of course, if the nano tube piece 154 is to make contact with the upper electrode 168, a charge opposite to the type of the charge applied to the nano tube piece 154 is applied to the upper electrode 168 and the same charge as the type of the charge applied to the nano tube piece 154 is applied to the lower electrode 112.

Therefore, the conventional memory device stores one bit data corresponding to a state in which the nano tube piece 154 is floated between the lower electrode 112 and the upper electrode 168 and a state in which the nano tube piece 154 makes contact with the lower electrode 112 or the upper electrode 168.

However, the conventional memory device has the following disadvantages.

First, since the horizontal distance of the nano tube piece 154 supported by both upper ends of the lower electrode 112 should be greater than the vertical distance by which the nano tube piece 154 is moved upward and downward and the distance between adjacent lower electrodes 112 should be wider, the degree of integration of the device is lowered.

Second, in the case that the nano tube piece 154 is to be brought into contact with the lower electrode 112, since a high voltage should be applied between the nano tube piece 154 and the lower electrode 112 to overcome the tension of the nano tube piece 154 supported on both sides by a nitride layer on the first interlayer insulating layer 176, the power consumption is increased.

Third, when the nano tube piece 154 in which predetermined information is written is bent in one direction, the nano tube piece 154 making contact with the lower electrode 112 or the upper electrode 168 may be separated from the lower or upper electrode by a horizontal force and the written information can be lost as a result of the contact of the nano tube piece 154. Therefore, a spatial restriction is imposed in the conventional memory device by which a substrate fixed by a plate should be used, such as a semiconductor substrate of a silicon material. Further, since the conventional memory device is sensitive to an external impact, the productivity is deteriorated.

Fourth, since a predetermined charge should be continuously supplied to the lower electrode 112 or the upper electrode 168 making contact with the nano tube piece 154 in order to maintain the contact state of the lower electrode 112 or the upper electrode 168 with the nano tube piece 154, consumption of standby power is increased. Further, when the supply of the charge is stopped, since the written state of the information corresponding to the contact of the nano tube piece 154 cannot be maintained, it is impossible to realize the nonvolatile memory device.

### SUMMARY OF THE INVENTION

Therefore, in accordance with the present invention, there is provided a memory device capable of increasing the integration by reducing the distance between adjacent electrodes or interconnections in a plane structure and a method of manufacturing the same.

Also in accordance with the present invention, there is provided a memory device capable of reducing the power consumption by switching a portion to be switched between a plurality of electrodes at a low voltage.

Also in accordance with the present invention, there is provided a memory device capable of improving or maximizing productivity by reducing the spatial restriction so that written information is not lost even when a substrate is bent and minimizing damage due to an external impact.

Also in accordance with the present invention, there is provided a memory device having a nonvolatile property by reducing consumption of standby power to maintain written information and by preventing loss of information without supplied charge from outside.

In accordance with one aspect of the present invention, there is provided a memory device comprising: a bit line formed in one direction; a plurality of word lines provided above the bit line insulated from and crossing the bit line, the word lines being formed in parallel to one another, with a vacant space being formed therebetween having a predetermined interval; a flip electrode electrically connected to the bit line crossing the word lines, formed over one of the word lines above the bit line so as to pass through the vacant space, and configured to be bent in one direction with respect to the plurality of word lines by electric fields induced between the plurality of word lines; and a contact part configured to concentrate charges induced by the flip electrode in response to charges applied by the word line between the flip electrode and the bit line, the contact part protruding from a lower end of the flip electrode to have a predetermined thickness in the direction of the word line to reduce the length by which the flip electrode must be bent to selectively bring the word line and the flip electrode into contact.

The memory device can further comprise a trench separating the plurality of word lines lengthwise and separating the flip electrode and the contact part to make the plurality of word lines, the plurality of flip electrodes, and the plurality of contact parts symmetrical about the trench.

The memory device can further comprise a trap site formed on the word line adjacent to the bit line so as to be insulated from the word line and the contact part, the trap site configured to trap a predetermined charge applied from the word line or external to the device so as to electrostatically fix the contact part moved in the direction of the word line in the interior of the vacant space.

According to another aspect of the present invention, there is provided a memory device comprising: a substrate having a flat surface; a bit line formed on the substrate in one direction; a first interlayer insulating layer and a first word line stacked in a direction crossing the bit line; a second word line separated from the first word line by a predetermined interval so as to form a vacant space and formed in a direction parallel to the first word line; a second interlayer insulating layer and a third interlayer insulating layer formed on the substrate on a side surface of the first word line so as to support a side surface of the second word line by a predetermined height; a flip electrode electrically connected to the bit line at a portion adjacent to the first word line and passing through the vacant space above the first word line, the flip electrode configured to be bent upward and downward by an electric field induced between the first word line and the second word line; and a contact part formed to protrude from a lower end of the flip electrode in the direction of the first word line by a predetermined thickness to reduce the length by which the flip electrode should be vertically bent to come into contact with the first word line, the contract part being a part where charges induced in the flip electrode in response to charges applied to the first word line are concentrated.

The memory device can further comprise a first sacrificial layer and a second sacrificial layer stacked to be removed from sidewalls thereof exposed by the trench by an etching solution or a reaction gas to form the vacant space between the first word line and the second word line.

The first sacrificial layer and the second sacrificial layer can respectively comprise polysilicon layers.

The contact part can comprise a conductive metal layer filling in a dimple or a groove formed by recessing a central upper portion of the first sacrificial layer by a predetermined depth in the direction of the first word line.

The memory device can further comprise a spacer formed between the flip electrode and a side surface of a stack comprising the first interlayer insulating layer, the first word line, and the first sacrificial layer.

The spacer can comprise at least one of a silicon nitride layer and a polysilicon layer.

When the spacer is formed of a polysilicon layer, the polysilicon layer may be removed to form a second vacant space between a sidewall of the first word line and the flip electrode.

The distance between the first word line and the contact part can be smaller than the distance of the second vacant space formed between the sidewall of the first word line and the flip electrode.

The memory device can further comprise a trench separating the first word line on the first interlayer insulating layer, the flip electrode, the contact part, and the second word line.

The flip electrode and the contact part respectively can comprise titanium, a titanium nitride layer, or a carbon nano tube.

The memory device can further comprise a trap site formed on the first word line so as to be insulated from the first word line and the contact part, the trap site being configured to trap a predetermined charge applied from the first word line or external to the device so as to electrostatically fix the contact part moved in the direction of the first word line in the interior of the vacant space.

The trap site can have a structure in which a silicon oxide layer, a silicon nitride layer, and a silicon oxide layer are stacked to have a predetermined thickness.

According to another aspect of the present invention, there is provided a method for manufacturing a memory device comprising: forming a bit line in one direction on a substrate; forming a stack comprising a first interlayer insulating layer, a first word line, and a first sacrificial layer in a direction crossing the bit line; forming a spacer on each longitudinal sidewall of the stack; forming a dimple by recessing a central upper portion of the first sacrificial layer by a predetermined depth; forming a flip electrode and a contact part to extend between portions of the bit line adjacent to the spacers to cover the first sacrificial layer with the dimple and to be electrically connected to the bit line; forming a second interlayer insulating layer covering the entire surfaces of the substrate and the bit line on which the flip electrode and the contact part are formed and exposing the flip electrode and the contact part on the stack; forming a second sacrificial layer and a second word line in the direction of the stack on the flip electrode and the contact part; forming a third interlayer insulating layer covering the entire surface of the substrate flat and partially opening an upper portion of the second word line in the lengthwise direction; forming a trench having a predetermined depth by sequentially removing the second word line exposed by the third interlayer insulating layer, the second sacrificial layer, the flip electrode, the contact part, the first sacrificial layer, and the first word line; and forming a vacant space between the first word line and the second word line by removing the first sacrificial layer and the second sacrificial layer from the sidewalls thereof exposed by the trench so as to float the flip electrode and the contact part in the vacant space.

In the method, the stack may further include a trap site comprising a first silicon oxide layer, a silicon nitride layer, and a second silicon oxide layer between the first word line and the first sacrificial layer.

The trench can be formed so as to separate the trap site into two portions symmetrically divided by the trench.

The forming of the third interlayer insulating layer may include reducing the line width of a hard mask layer used to pattern the second sacrificial layer and the second word line, forming a silicon oxide layer to bury the hard mask layer, partially removing the silicon oxide layer to planarize the silicon oxide layer until a top surface of the hard mask layer is exposed, and removing the hard mask layer to expose a central upper portion of the second word line.

The method can further comprise forming a fourth interlayer insulating layer sealing the interior of the trench by covering an upper end of the trench.

### BRIEF DESCRIPTION OF THE DRAWINGS

The present invention will become more apparent to those of ordinary skill in the art in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the invention. In the drawings:

FIG. 1 is a cross-sectional view illustrating a conventional memory device;

FIG. 2 is a perspective view illustrating a first embodiment of a memory device according to an aspect of the present invention;

FIG. 3 is a cross-sectional view taken along line I-I′ of FIG. 2;

FIG. 4 is a cross-sectional view illustrating an embodiment of a structure in which the memory devices of FIG. 2 are stacked;

FIGS. 5A to 6K are perspective views and cross-sectional views for explaining an embodiment of a method of manufacturing the memory device of FIGS. 2 and 3;

FIG. 7 is a perspective view illustrating a second embodiment of a memory device according to an aspect of the present invention;

FIG. 8 is a cross-sectional view taken along line II-II′ of FIG. 7;

FIG. 9 is a graph representing a relationship between a voltage applied through a bit line and a write word line of the memory device according to the second embodiment and the bending distance of a flip electrode;

FIG. 10 is a cross-sectional view illustrating a structure in which the memory devices of FIG. 7 are stacked; and

FIGS. 11A to 12K are perspective views and cross-sectional views for explaining an embodiment of a method of manufacturing the memory device of FIGS. 7 and 8.

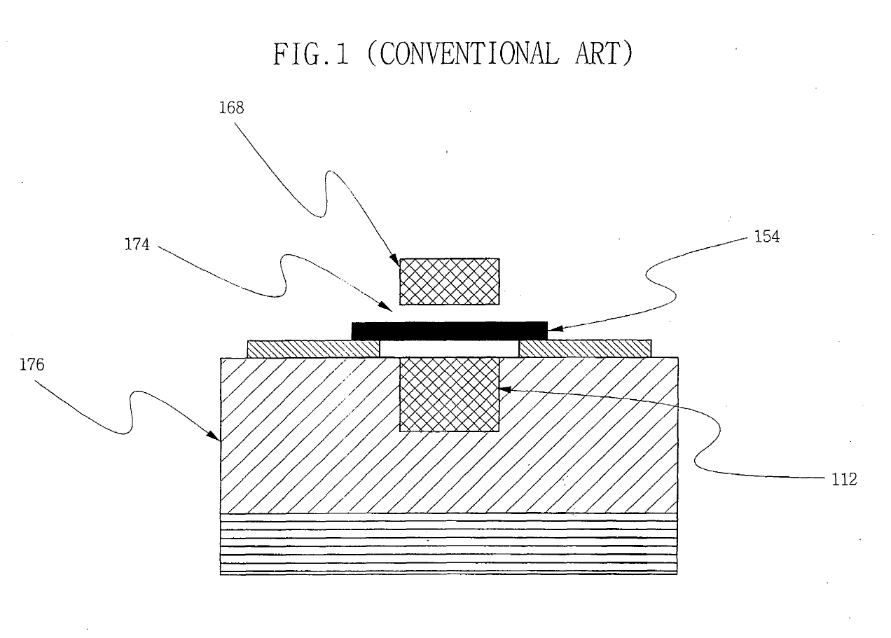

### DETAILED DESCRIPTION OF PREFERRED EMBODIMENTS

Hereinafter, embodiments of a memory device and a method for manufacturing the memory device according to aspects of the present invention will be described in detail with reference to the accompanying drawings. The invention can, however, be embodied in many different forms and should not be construed as being limited to the embodiments set forth herein. In the drawings, the thicknesses of various layers and regions are exaggerated for clarity. Further, when it is described that a layer exists ‘on’ another layer or a substrate, the layer can directly make contact with another layer or the substrate or a third layer can exist between the layer and another layer or the i s substrate.

It will be understood that, although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

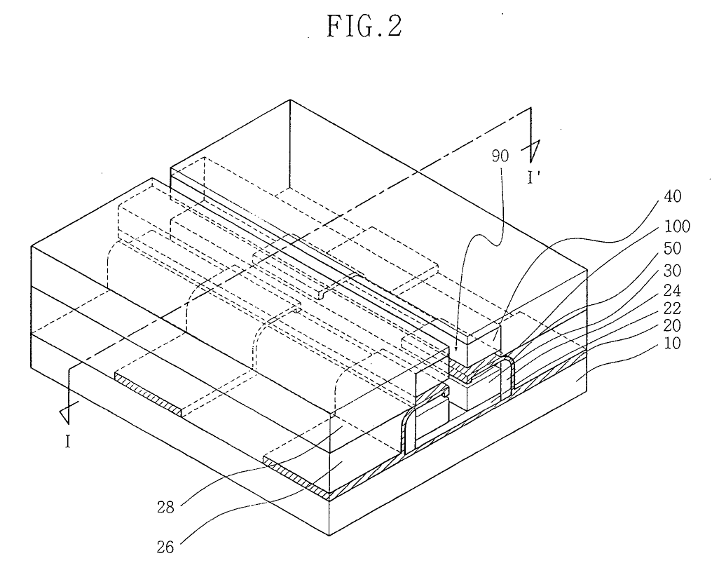

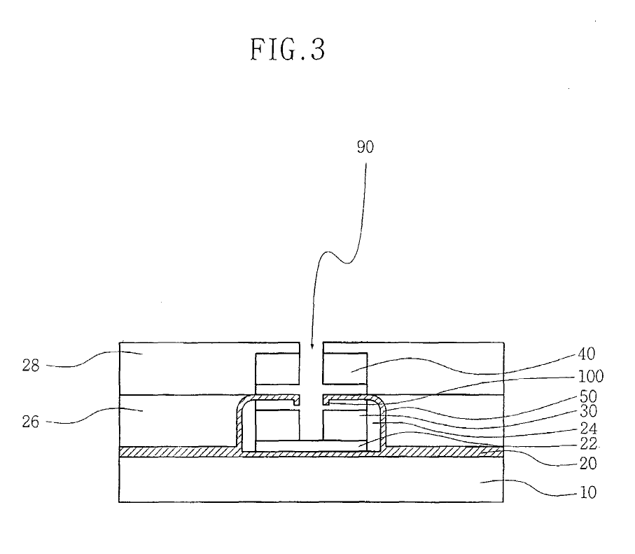

FIG. 2 is a perspective view illustrating a first embodiment of a memory device according to an aspect of the present invention. FIG. 3 is a cross-sectional view taken along the line I-I′ of FIG. 2.

As illustrated in FIGS. 2 and 3, the memory device according to the first embodiment includes a substrate 10 having a flat surface, a bit line 20 formed on the substrate 10 in one direction, a write word line (e.g. a first word line) 30 and a read word line (e.g. a second word line) 40 provided above the bit line 20, insulated from the bit line 20, crossing the bit line 20, having a vacant space therebetween, and being parallel to each other, a flip electrode 50 electrically connected to the bit line 20 crossing the write word line 30 and the read word line 40, covering the write word line 30 above the bit line 20 and passing through the vacant space, and bent in one direction by electric fields induced between the write word line 30 and the read word line 40, and a contact part 100 concentrating charges induced by the flip electrode 50 in response to charges applied by the write word line between the flip electrode 50 and the bit line 20 and protruding from the lower end of the flip electrode 50 by a predetermined thickness in the direction of the write word line 30 to reduce the length by which the flip electrode 50 is bent and to selectively bring the write word line 30 into contact with the flip electrode 50.

Here, the substrate 10 provides a flat surface so that the bit line 20 can be formed in one direction. For example, the substrate 10 includes an insulating substrate or a semiconductor substrate having an excellent flexibility by which the substrate 10 is bent by an external force.

The bit line 20 has a predetermined thickness on the substrate 10 and is formed in one direction. Further, the bit line 20 is formed of a material having an excellent electrical conductivity. For example, the bit line 20 can be formed of a conductive metal material having an excellent conductivity such as gold, silver, copper, aluminum, tungsten, tungsten silicide, titanium, titanium nitride, tantalum, and tantalum silicide, or a silicon or polysilicon material doped with conductive impurities. Although not illustrated, a first hard mask layer used to pattern the bit line 20 including the conductive metal material or the polysilicon material can have a line width equal to or similar to the bit line 20 between the write word line 30 and the bit line 20.

The write word line 30 crosses the bit line 20 above the substrate 10 and is insulated from the bit line 20. Similarly, the write word line 30 can be formed of a conductive metal material such as gold, silver, copper, aluminum, tungsten, tungsten silicide, titanium, titanium nitride, tantalum, and tantalum silicide. Then, the write word line 30 and the bit line 20 are separated from each other, with a first interlayer insulating layer 22 having a predetermined thickness being interposed between the write word line 30 and the bit line 20, to decrease the interference therebetween. The first interlayer insulating layer 22 has the same direction as the write word line 30. This is because the bit line 20 should be exposed on a side surface of the write word line 30 when the flip electrode 50 is formed in order to bring the flip electrode 50 formed above the write word line 30 into contact with the bit line 20. Further, the first interlayer insulating layer 22 can be used as an etch stop layer when forming a trench 90 symmetrically separating a plurality of write word lines 30, a plurality of flip electrodes 50, and a plurality of read word lines above the bit line 20. For example, the first interlayer insulating layer 22 can include one or more of a silicon oxide layer, a silicon nitride layer, and a silicon oxynitride layer.

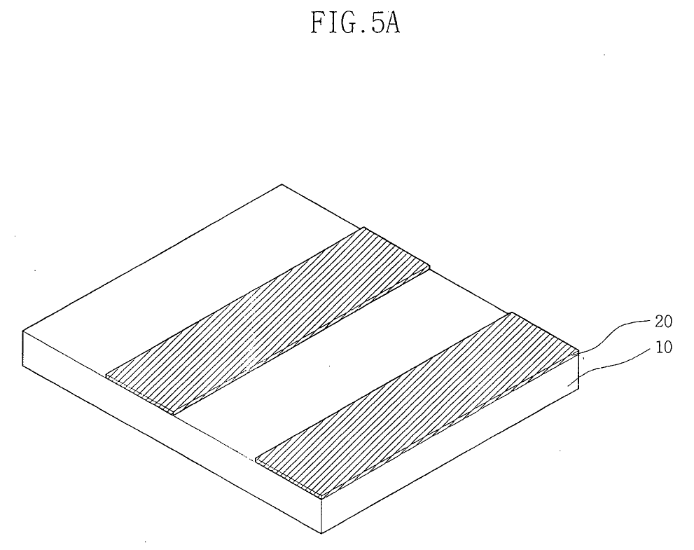

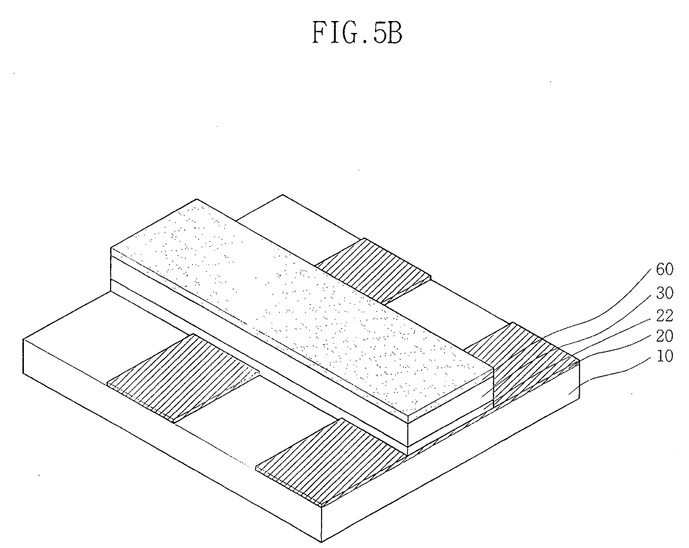

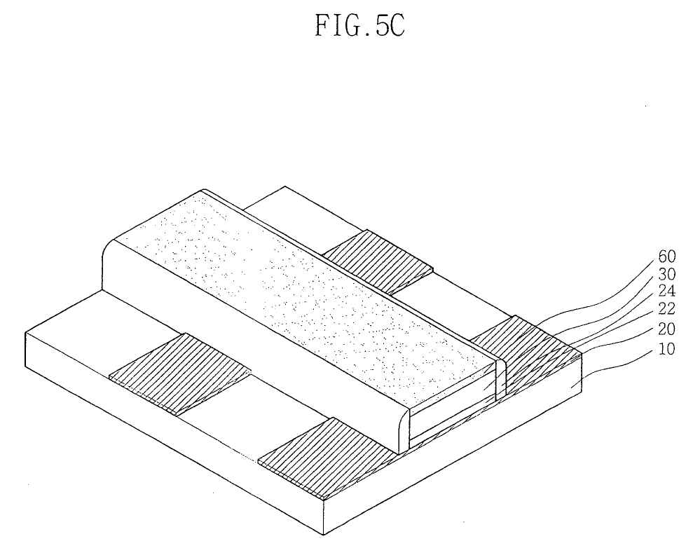

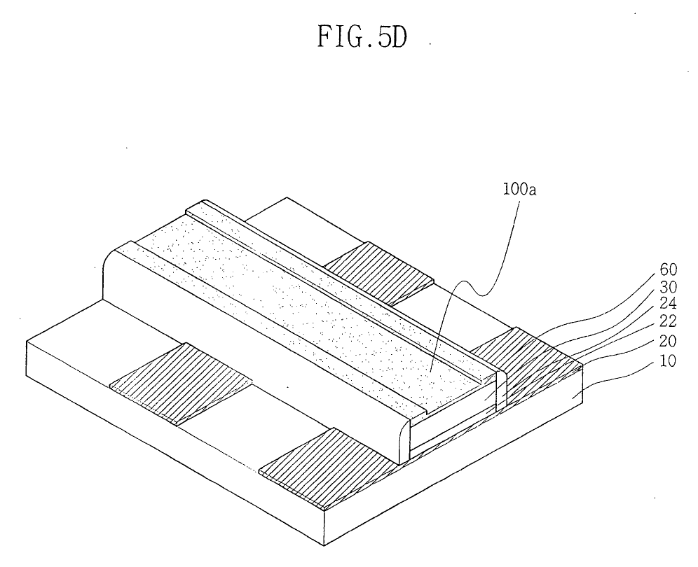

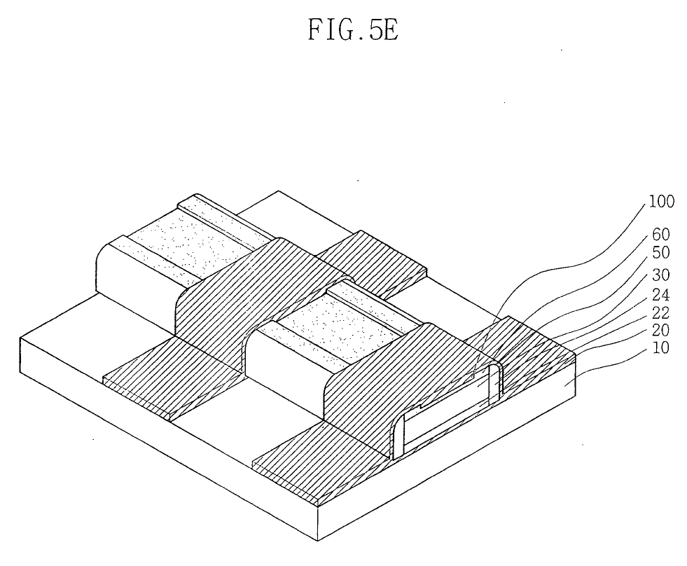

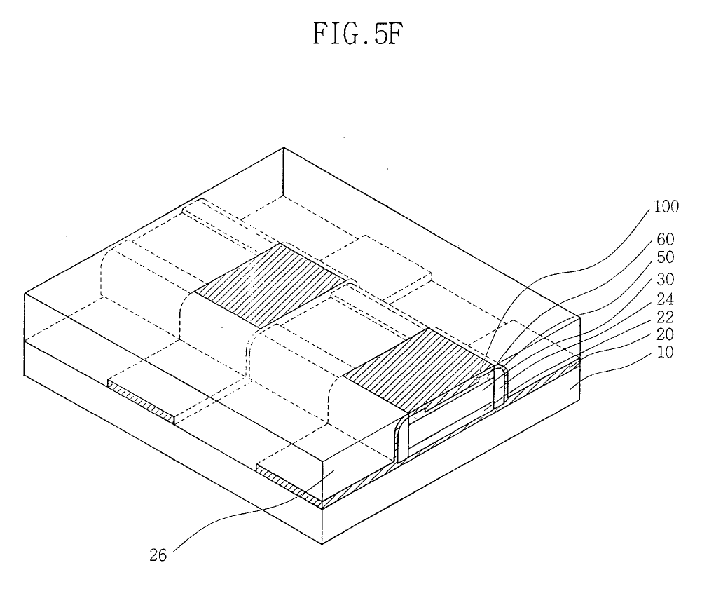

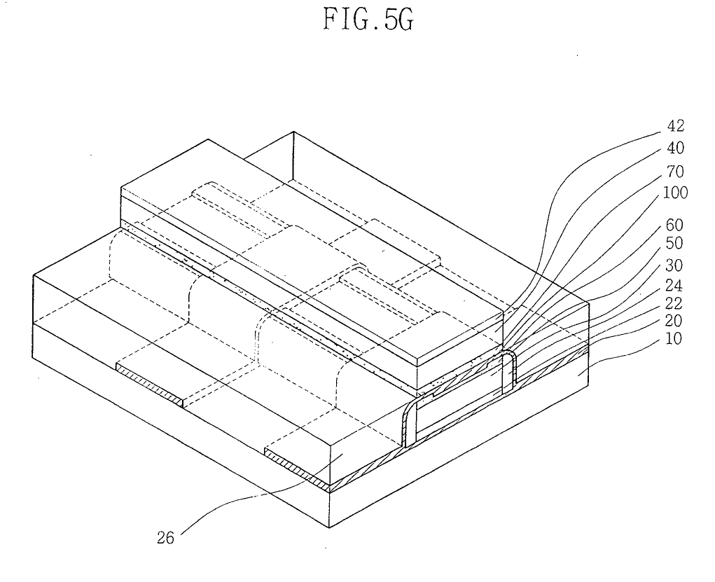

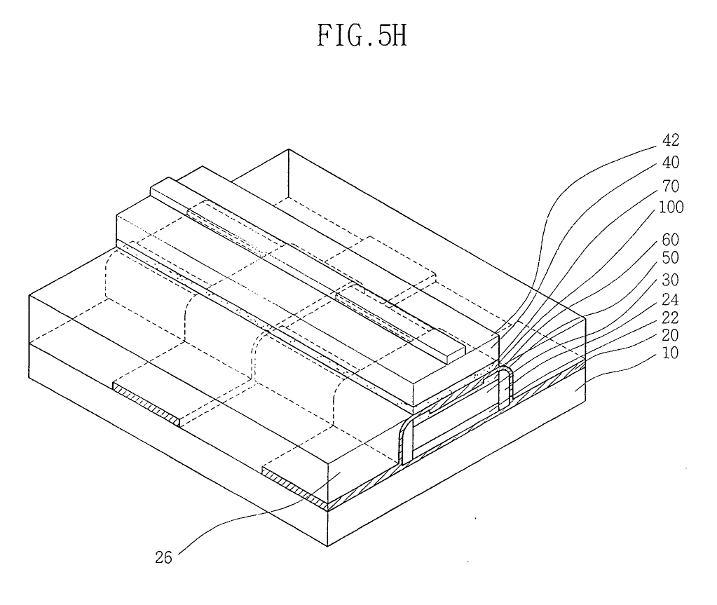

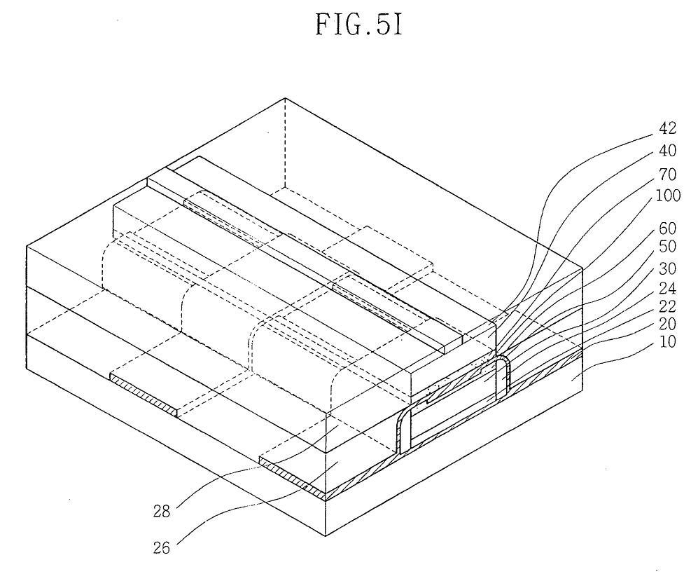

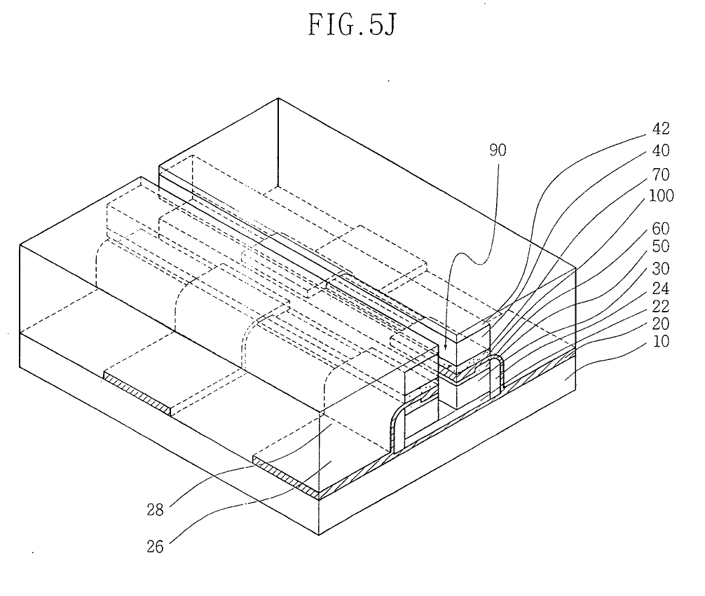

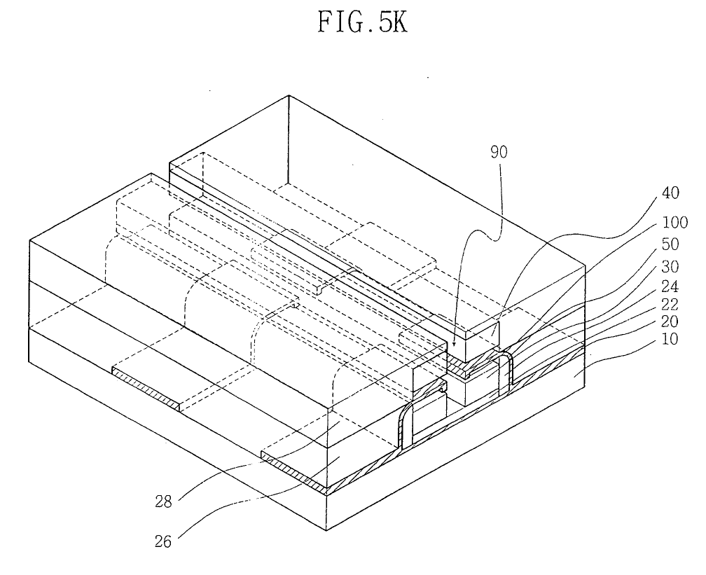

Although not illustrated, the memory device according to the first embodiment includes a first sacrificial layer 60 (FIG. 5B) stacked on the write word line 30 so that the flip electrode 50 can be separated from and above the write word line 30 and removed so that the vacant space is formed between the write word line 30 and the flip electrode 50 through the trench 90. Here, the first sacrificial layer 60 has a predetermined thickness on the write word line 30 and has a line width equal to or similar to that of the write word line 30. The first sacrificial layer 60 is introduced through the trench 90 opening the first interlayer insulating layer 22 in the direction of the write word line 30 and is removed by an etching solution or a reaction gas having an excellent etch selectivity. For example, the first sacrificial layer 60 can be formed of a polysilicon material. Therefore, the first sacrificial layer 60 is formed to define the vacant space in which the flip electrode 50 can be bent. Further, a contact part 100 is defined by a dimple 100a (FIG. 5D) or a groove in which the center of the first sacrificial layer 60 is recessed by a predetermined depth in the direction of the write word line 30.

A spacer 24 is formed between a side surface of a stack including the first interlayer insulating layer 22, the write word line 30, and the first sacrificial layer 60, and the flip electrode 50. Here, the spacer 24 separates the flip electrode 50 from a sidewall of the write word line 30 by a predetermined distance. The spacer 24 has a height corresponding to an upper end edge of the vacant space formed between the flip electrode 50 and the write word line 30, or an upper end edge of the first sacrificial layer 60, and surrounds the side surface of the stack. For example, the spacer 24 can be formed of an insulating layer material, such as a silicon nitride layer. When the spacer 24 is formed of a polysilicon material such as a silicon nitride layer like the first sacrificial layer 60, it can be removed together with the first sacrificial layer 60 by an etching solution or a reaction gas having an etch selectivity equal to or similar to that of the first sacrificial layer 60 to form the vacant space between the sidewall of the stack and the flip electrode 50.

The flip electrode 50 is electrically connected to the bit line 20 adjacent to the stack and extends to an upper portion of the stack along the side surface of the stack. The flip electrode 50 has a line width equal to or similar to that of the bit line 20 and is formed in the direction of the bit line 20. The flip electrode 50 is disposed over the first interlayer insulating layer 22 and the write word line 30 crossing the bit line 20. Then, a plurality of flip electrodes 50 are symmetrically separated on both sides about the trench 90 symmetrically separating the plurality of the write word lines 30. The flip electrode 50 is formed of a conductive material having a predetermined resiliency to be freely moved upward and downward by an electric field induced in the vacant space formed between the write word line 30 and the read word line 40. For example, the flip electrode 50 can be formed of titanium, a titanium nitride layer, or a carbon nano tube material. Then, the carbon nano tube forms a pipe shape by connecting hexagonal shapes including six carbon atoms. The name of carbon nano tube comes from the diameter of the pipe being merely several to tens of nanometers. The electric conductivity of the carbon nano tube is similar to that of copper and the thermal conductivity of the carbon nano tube is substantially the same as that of diamond, which is very high. Further, the strength of the carbon nano tube is about 100 times stronger than steel. The carbon nano tube has a restoring force high enough to be suitable for fifteen percent of deformation, while a carbon fiber is broken by one percent of deformation.

Then, the flip electrode 50 can be bent upward and downward above the write word line 30. An inner surface of the flip electrode 50 is fixed by the spacer 24 formed on a side surface of the write word line 30. Further, if the spacer 24 is not provided and a vacant space is formed on the sidewall of the stack, the flip electrode 50 can be fixed by the second interlayer insulating layer 26 on the outer side of the flip electrode 50. Here, the second interlayer insulating layer 26 has a height equal to or similar to that of the flip electrode 50. Although not shown, the second interlayer insulating layer 26 can have a height equal to or similar to that of a third hard mask layer formed on the flip electrode 50 to pattern the flip electrode 50. For example, the second interlayer insulating layer 26 can be formed of a silicon oxide layer material. Then, the second interlayer insulating layer 26 has a flat surface together with the flip electrode 50 or the third hard mask layer of the flip electrode 50 to pattern the second sacrificial layer 70 and the read word line 40 in subsequent processes.

The contact part 100 protrudes in the direction of the write word line 30 from the distal end of the flip electrode 50 above the write word line 30 crossing the bit line 20. For example, the contact part 100 can be formed together with the flip electrode 50 by the dimple 100a or the groove in which the center of the first sacrificial layer 60 formed on the write word line 30 is recessed by a predetermined depth. Although not shown, the contact part 100 can be formed by filling the same conductive metal material as the flip electrode 50 in the dimple 100a or the groove removed by a predetermined depth isotropically or anisotropically using a wet etching method or a dry etching method which uses a second hard mask layer exposing a central upper portion of the first sacrificial layer 60 as an etch mask. Therefore, the contact part 100 protrudes from the most distal end of the flip electrode 50 in the direction of the write word line 30. Further, if the first sacrificial layer 60 is removed, the flip electrode 50 and the contact part 100 can be floated by predetermined heights with respect to the write word line 30. Therefore, the contact part 100 is formed so as to reduce the bent distance of the flip electrode 50 which is bent in the direction of the write word line 30 under a predetermined condition. The bent distance of the flip electrode 50 can be reduced in correspondence to the thickness of the contact part 100. If charges of different polarities are applied to the write word line 30 and the flip electrode 50 at a predetermined voltage, the flip electrode 50 can be bent in the direction of the write word line 30. Then, the charges applied through the flip electrode 50 can be concentrated to the contact part 100. For example, since the charges applied to the flip electrode 50 are concentrated by Gauss's law, an attraction force is applied to the contact part 100 in the direction of the write word line 30 to bend the flip electrode 50. The relationship between the electric field and the voltage induced between the contact part 100 and the write word line 30 and the bending of the flip electrode 50 will be described later.

Although not illustrated, the memory device according to the first embodiment further includes a second sacrificial layer 70 formed on the flip electrode 50 to separate the read word line 40 from the flip electrode 50 by a predetermined distance and removed so that a vacant space is formed between the flip electrode 50 and the read word line 40 in the sidewall exposed by the trench 90. Here, like the first sacrificial layer 60, the second sacrificial layer 70 can be isotropically etched by an etching solution or a reaction gas introduced into the interior of the trench 90 to be removed. For example, the second sacrificial layer 70 can define the distance by which the flip electrode 50 is bent in the direction of the read word line 40 and is formed of a polysilicon material like the first sacrificial layer 60.

Further, the read word line 40 is stacked on the second sacrificial layer 70 and has a line width equal to or similar to that of the second sacrificial layer 70. For example, the read word line 40 can be formed of a conductive metal material such as gold, silver, copper, aluminum, tungsten, tungsten silicide, titanium, titanium nitride, tantalum, and tantalum silicide. A vacant space is formed between the read word line 40 and the flip electrode 50. Therefore, a third interlayer insulating layer 28 supporting a side surface of the read word line 40 is formed on the second interlayer insulating layer 26 to float the read word line 40 above the flip electrode 50 if the second sacrificial layer 70 on the flip electrode 50 is removed to form the vacant space. Here, the third interlayer insulating layer 28 can be used as a mask layer to symmetrically form a plurality of read word lines 40, a plurality of flip electrodes 50, and a plurality of write word lines 30 about the trench 90 when the trench 90 is formed. Then, the third interlayer insulating layer 28 is planarized so that a fourth hard mask layer 42 (FIG. 5G) on the read word line 40 can be opened. Further, the third interlayer insulating layer 28 is planarized so that a photoresist pattern opening an upper portion corresponding to the fourth hard mask layer 42 formed on the read word line 40 can be formed.

The trench 90 can form a plurality of read word lines 40, a plurality of flip electrodes 40, and a plurality of write word lines 30 symmetrically by respectively separating the read word line 40, the flip electrode 50, the contact part 100, and the write word line 30. For example, the trench 90 can be formed to have a direction equal to or similar to those of the write word line 30 and the read word line 40 and to separate the flip electrode 50 while crossing the flip electrode 50 and the bit line 20 at a right angle. Then, the trench 90 exposes the first interlayer insulating layer 22 to the bottom surface.

Therefore, since the memory device according to the first embodiment includes the trench 90 separating the read word line 40 and the write word line 30 with vacant spaces, to both sides in the lengthwise direction and separating the flip electrode 50 and the contact part 100 electrically connected to the bit line 20 below the write word line 30 so that the distances between a plurality of lines having a symmetrical structure about the trench 90 can be reduced, thereby increasing the integration density of unit devices.

Meanwhile, if a predetermined charge is applied to the contact part 100 through the bit line 20 and the flip electrode 50, the contact part is moved upward and downward by the electric field induced in the vacant space between the write word line 30 and the read word line 40 to make contact with the write word line 30 or the read word line 40. For example, the contact part 100 can be moved in the direction of the write word line 20 30 or the read word line 40 by the Coulombic force indicated by Formula 1.

$$F = - k \frac{{q}_{1} {q}_{2}}{{r}^{2}} = - {q}_{1} E \qquad Formula 1$$

Here, ‘k’ is Coulomb's force constant, ‘q₁’ is the charge applied to the contact part 100 formed at the distal end of the flip electrode 50, and ‘q₂’ is the charge applied to the write word line 30 or the read word line 40. Further, ‘r’ is the straight distance between the write word line 30 and the contact part 100. Further, ‘E’ is the electric field induced between the write word line 30 and the flip electrode 50 or between the write word line 40 and the contact part 100. According to the Coulombic force, if the “q₁” and the ‘q₂’ have the opposite polarities, an attractive force is applied between them so that they can become closer. As mentioned above, the charges applied through the flip electrode 50 are concentrated to the contact part 100. As the write word line 30 and the contact part 100 become closer or the read word line 40 and the contact part 100 become closer, more charges can be concentrated to the contact part 100. On the other hand, if the “q₁” and the ‘q₂’ have the same polarity, a repulsive force is applied between them so that they can become more remote or distant from each other. Therefore, digital information corresponding to one bit can be written or read, and the one bit information corresponds to ‘0’ and ‘1’, respectively, depending on the state in which the contact part 100 and the write word line 30 are in an electrical contact, and the state in which they are electrically separated.

Further, as the distance between the contact part 100 and the write word line 30 becomes smaller, the Coulomibic force applied between the contact part 100 and the record word line 30 increases. As the Coulombic force increases, the flip electrode 50 20 can be easily bent in the direction of the write word line 30. Similarly, as the distance between the contact part 100 and the write word line 30 decreases, the voltage applied between the contact part 100 and the write word line 30 also decreases.

Therefore, the memory device according to the first embodiment includes the contact part 100 protruding in the direction of the write word line 30 from the distal end of the flip electrode 50 bent in the direction of the write word line 30 to reduce the bent distance of the flip electrode 50. Further, since the voltage applied between the contact part 100 and the write word line 30 can be reduced to bring the contact part 100 and the write word line 30 into electrical contact with each other, the power consumption can be reduced.

Then, the flip electrode 50 is fixed by the spacer 24 and the first interlayer insulating layer 22 and has an elastic force proportional to a predetermined modulus of elasticity. The flip electrode 50 is bent upward and downward while resisting the Coulombic force. For example, since the elastic force increases in proportion to a distance and the Coulombic force decreases in proportion to the square of the distance, as the distance between the contact part 100 and the write word line 30 decreases, the Coulombic force increases far more as compared to the elastic force. In addition, since the magnitude of the voltage applied between the contact part 100 and the write word line 30 can be decreased to overcome the elastic force, the power consumption can also be decreased.

Hereinafter, the writing and reading operations of the memory device according to the first embodiment using the Coulombic force applied between the write word line 30 and the contact part 100 will be described.

First, if charges having different polarities are applied to the contact part 100 and the write word line 30, an attractive force is generated between the contact part 100 and the write word line 30 and the contact part 100 can be bent to make contact with the write word line 30. Further, the charges having the same polarity as that of the charges applied to the contact part 100 can be applied to the read word line 40 so that a repulsive force is applied between the contact part 100 and the read word line 40 to bend the flip electrode 50 to the write word line 30. As mentioned above, as the distance between the write word line 30 and the contact part 100 becomes closer, the Coulombic force applied between the write word line 30 and the contact part 100 can further increase. Therefore, charges having different polarities can be supplied to the write word line 30 and the contact part 100 to bring the write word line 30 and the contact part 100 into electrical contact with each other. Further, when the contact part 100 and the write word line 30 are in electrical contact with each other, only if charges having different polarities are supplied to the contact part 100 and the write word line 30 at a predetermined intensity or higher, will the contact part 100 and the write word line 30 continuously maintain the contact state. This is because the electrostatic force represented by the Coulombic force is several tens of thousands times stronger than a general elastic force or a restoring force and thus can overcome the elastic force of the flip electrode 50 to maintain the contact state of the contact part 100 and the write word line 30.

Meanwhile, if charges having a same polarity are supplied to the contact part 100 and the write word line 30, a repulsive force is applied between the contact part 100 and the write word line 30 to separate the contact part 100 and the write word line 30. Further, charges having a polarity different from that of the charges applied to the contact part 100 can be applied to the read word line 40 so that the flip electrode 50 can be bent in the direction of the read word line 40. Then, although charges applied to the write word line 30 have a polarity opposite to that of the charges applied to the contact part 100, if the charges applied to the write word line 30 do not have a predetermined intensity or higher, the contact part 100 and the write word line 30 cannot make contact with each other. This is because when the contact part 100 and the write word line 30 are separated from each other by a predetermined distance ‘r’ or more, although charges having different polarities and having a predetermined intensity or less are respectively applied to the contact part 100 and the write word line 30, they cannot overcome the Coulombic force applied as an attractive force between the contact part 100 and the read word line 40.

Therefore, the memory device according to the first embodiment can write one bit information corresponding to a state in which the contact part 100 makes electrical contact with or is separated from the write word line 30 by applying charges having a predetermined polarity and having a predetermined intensity or higher to the contact part 100 and the write word line 30. Further, when charges having a polarity different from that of the charges applied to the contact part 100 and having a predetermined intensity or less are applied to the write word line 30 and charges having a polarity opposite to that of the charges applied to the contact part 100 and having a predetermined intensity or higher are applied to the read word line 40, the information corresponding to the state that the contact part 100 makes electrical contact with or is separated from the write word line 30 can be read.

Then, the contact part 100 is prevented from being easily deformed by an external force when the contact part 100 makes contact with the write word line 30 or is separated from the write word line 30. For example, even when the substrate 10 is bent upward and downward in the state that the contact part 100 makes contact with the write word line 30, the contact part 100 only slides to the right and to the left about the trench 90 but maintains the contact state of the write word line 30. Similarly, even when the contact part 100 is separated from the write word line 30, the contact part 100 only becomes distant from the write word line 30 or closer to the write word line 30 right or left about the trench 90, but the contact part 100 and the write word line 30 maintain their separated state.

Therefore, since the memory device according to the first embodiment includes the contact part 100 making contact with or separated from a plurality of write word lines 30 and formed at the distal ends of a plurality of flip electrodes 50 about the trench 90, it can continuously maintain the state in which the flip electrodes 50 make contact with or are separated from the write word lines 30 even when the substrate 10 is bent. Accordingly, the spatial restrictions can be reduced and damage due to an impact applied from outside can be minimized, thereby improving or maximizing the productivity.

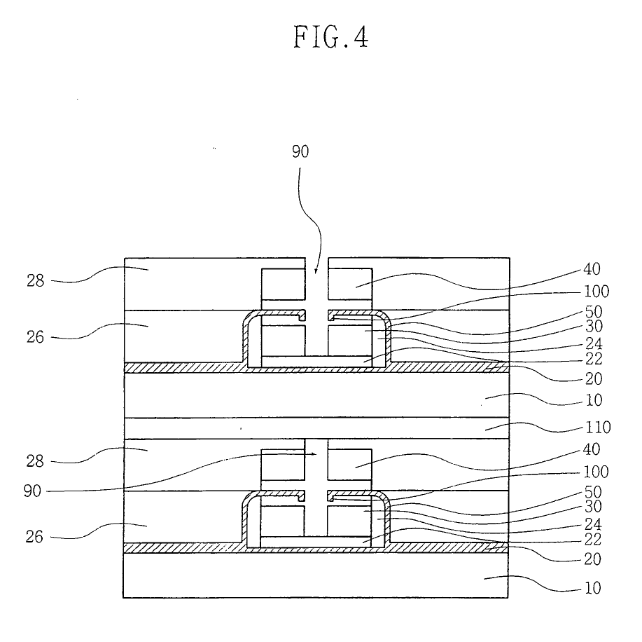

FIG. 4 is a cross-sectional view illustrating an embodiment of a stack structure of the memory device of FIG. 2. In the stack structure, a plurality of memory devices are sequentially stacked, each including the contact part 100 protruding in the direction of the write word line 30 from the distal end of the flip electrode 50 inserted into the vacant space between the write word line 30 and the read word line 40 above and insulated from the bit line 20, formed in one direction and crossing the bit line 20. Here, the memory devices each having a plurality of write word lines 30 and a plurality of read word lines 40 above the bit line 20 are formed, with a fourth interlayer insulating layer 110 being interposed therebetween. The fourth interlayer insulating layer 110 covers an upper portion of the trench 90 exposing the first sacrificial layer 60 (see FIG. 5B) and the second sacrificial layer 70 (see FIG. 5G) removed to form the vacant space between the read word line 40 and the write word line 30.

Although not illustrated, the bit lines 20 in the plurality of memory devices can be alternately formed. Further, at least one switching device, such as a transistor controlling a voltage applied to the memory device, can be formed at an outer periphery of the memory device. Furthermore, various devices, such as an MOS transistor, a capacitor, and a resistance, can be formed at a portion adjacent to the nonvolatile memory device.

Hereinafter, a method of manufacturing the memory device according to the first embodiment will be described.

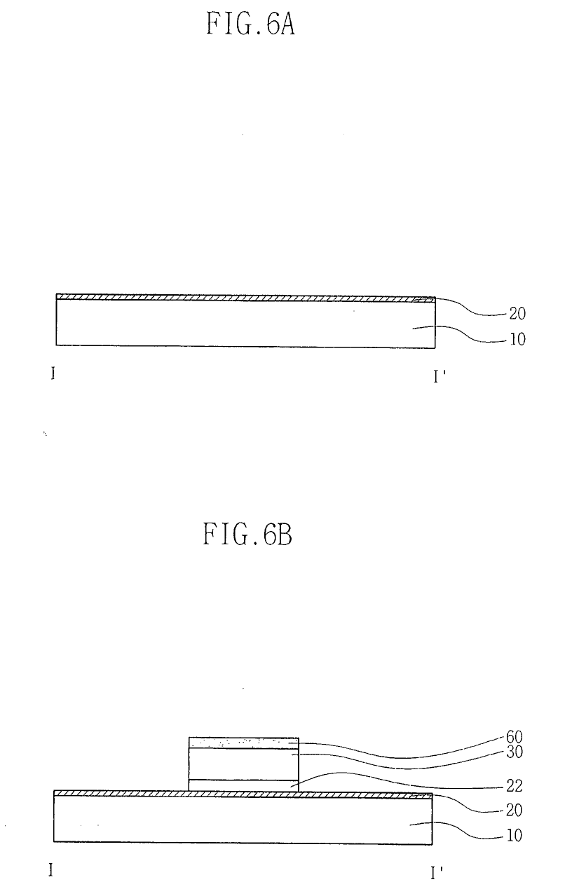

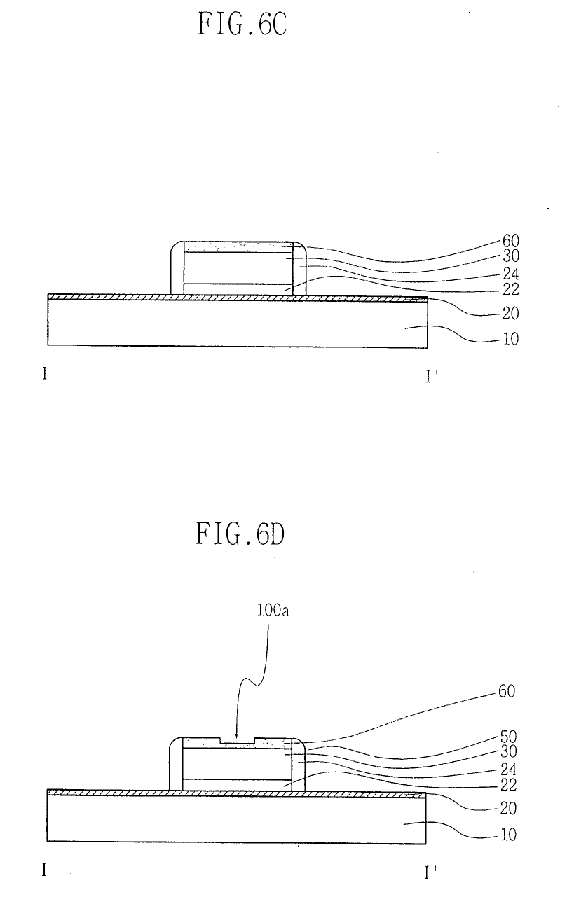

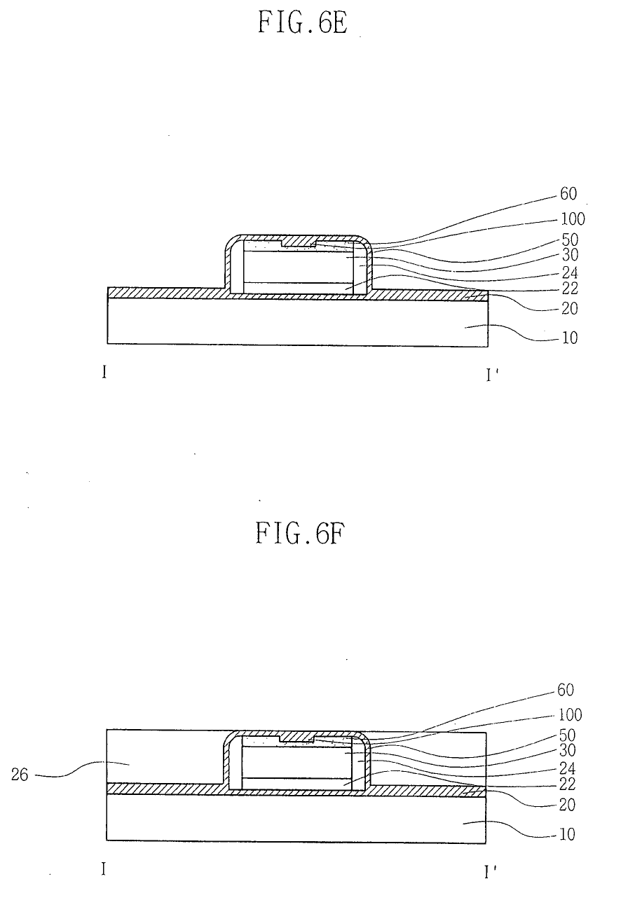

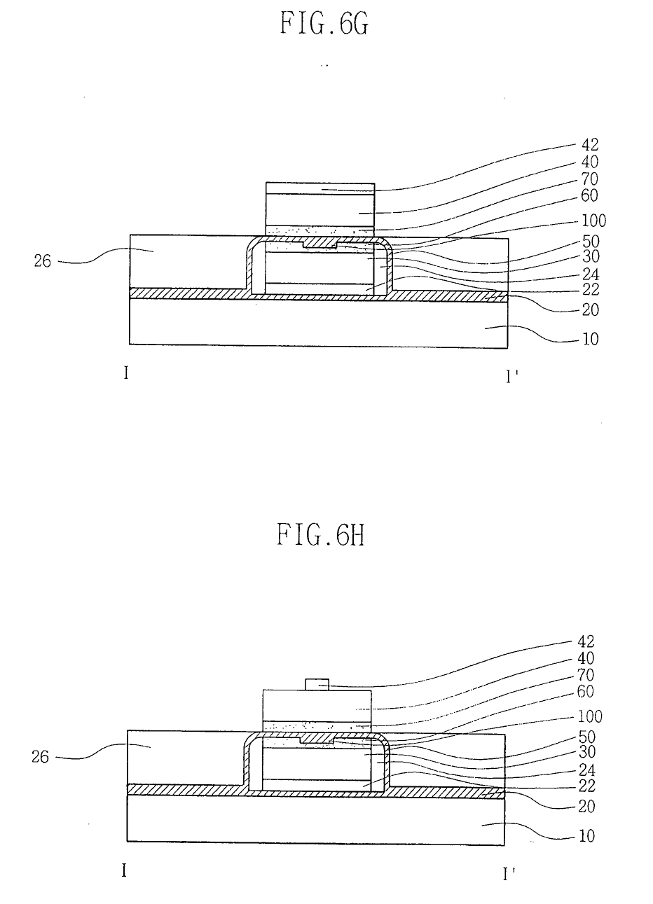

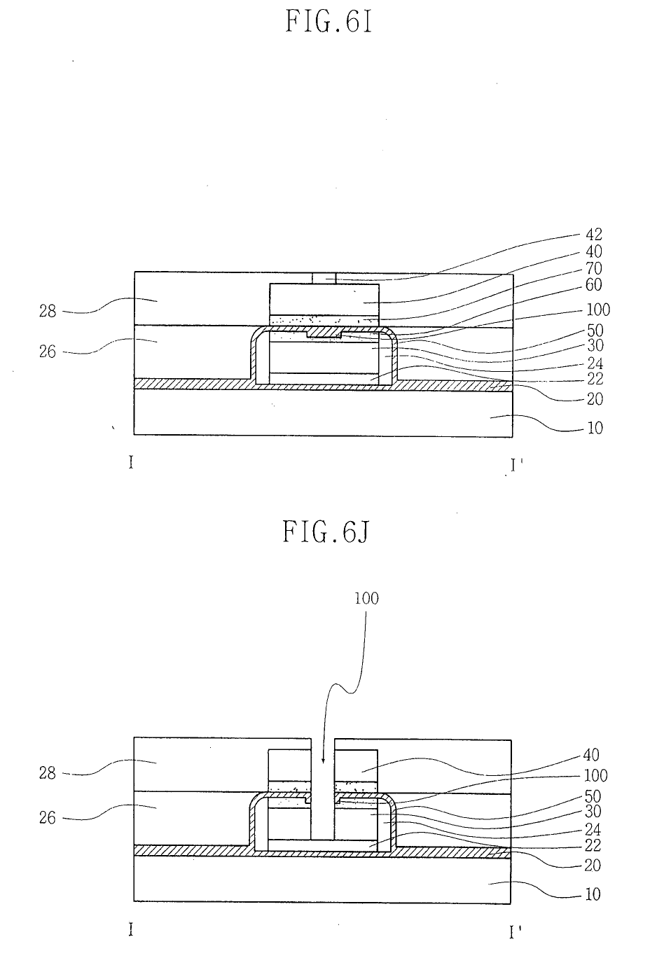

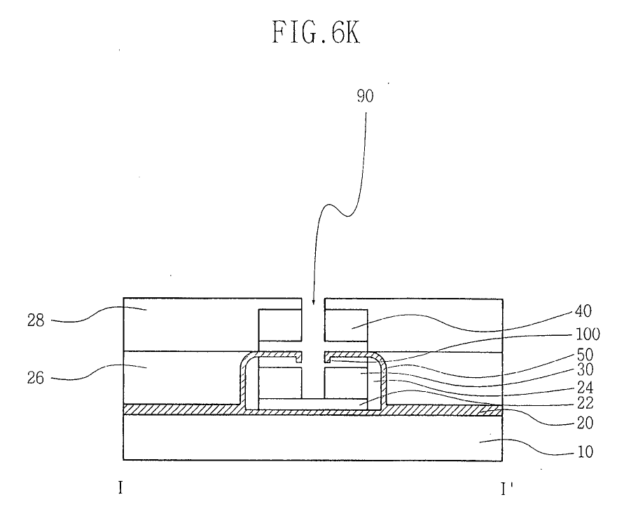

FIGS. 5A to 6K are perspective views and cross-sectional views for explaining an embodiment of a method of manufacturing the memory device of FIGS. 2 and 3. Here, the cross-sectional views of FIGS. 6A to 6K are obtained by cutting away the perspective views of FIGS. 5A to 5K and are sequentially illustrated.

As illustrated in FIGS. 5A and 6A, the bit line 20 having a predetermined thickness is formed on the horizontal substrate 10. Here, a plurality of bit lines 20 are formed in parallel to each other in one direction on the substrate 10. For example, the bit line 20 includes a conductive metal layer, such as gold, silver, copper, aluminum, tungsten, tungsten silicide, titanium, titanium nitride, tantalum, and tantalum silicide or a silicon or polysilicon layer doped with conductive impurities which can be manufactured by a physical vapor deposition method and a chemical vapor deposition method. Although not illustrated, the bit line 20 can be formed by a dry etching method using a photoresist pattern or a first hard mask layer as an etch mask layer, by etching the conductive metal layer or the polysilicon layer formed on the entire surface of the substrate 10 with a predetermined thickness. For example, the reaction gas used in the dry etching method of the conductive metal layer or the polysilicon layer includes a strong acid gas obtained by mixing sulfuric acid and nitric acid. The bit line 20 has a thickness of approximately 500 Å and a line width of approximately 30 Å to 500 Å, in this embodiment.

As illustrated in FIGS. 5B and 6B, the first interlayer insulating layer 22 having a predetermined line width in a direction crossing the bit line 20, the write word line 30, and the first sacrificial layer 60 are formed. Here, the first interlayer insulating layer 22, the write word line 30, and the first sacrificial layer 60 are stacked with respective predetermined thicknesses. The stack of the first interlayer insulating layer 22, the write word line 30, and the first sacrificial layer 60 are formed by anisotropically etching the stack by a dry etching method using one photoresist pattern formed on the first sacrificial layer 60 as an etch mask layer. For example, the first interlayer insulating layer 22 can include a silicon oxide layer or a silicon nitride layer formed to have a thickness of approximately 200 Å to 850 Å by a chemical vapor deposition method. Then, the first interlayer insulating layer 22 can function as an etch stop layer in a subsequent process of forming the trench 90 separating the write word line 30 lengthwise. Further, the write word line 30 can include a conductive metal layer such as gold, silver, copper, aluminum, tungsten, tungsten silicide, titanium, titanium nitride, tantalum, and tantalum silicide formed by a physical vapor deposition method or a chemical vapor deposition method to have a thickness of approximately 500 Å. The first sacrificial layer 60 can include a polysilicon layer formed by an atomic layer deposition method or a chemical vapor deposition method so as to have a thickness of approximately 50 Å to 150 Å. The first sacrificial layer 60, the write word line 30, and the first interlayer insulating layer 22 have line widths of approximately 30 Å to 1000 Å, in this embodiment. The reaction gas used in the dry etching method to pattern the first sacrificial layer 60, the write word line 30, and the first interlayer insulating layer 22 can be one or more of a group of carbon fluoride gases, such as a CxFy gas or a CaHbFc gas. The carbon fluoride gas can include CF₄, CHF₃, C₂F₆, C₄F₈, CH₂F₂, CH₃F, CH₄, C₂H₂, and C₄F₆ or a mixture gas thereof.

As illustrated in FIGS. 5C and 6C, the spacer 24 is formed on each of the longitudinal sidewalls of the stack including the first interlayer insulating layer 22, the write word line 30, and the first sacrificial layer 60. Here, the spacer 24 is selectively formed on the sidewall of the stack including the first interlayer insulating layer 22, the write word line 30, and the first sacrificial layer 60 which has a stepped portion, in order to insulate the flip electrode 50 from the write word line 30. For example, the spacer 24 can include a silicon nitride layer or a polysilicon layer formed by a chemical vapor deposition method. Then, the spacer 24 can be self-aligned on the sidewall of the stack by forming a silicon nitride layer or a polysilicon layer having a uniform thickness on the entire surface of the substrate 10 and by anisotropically etching the silicon nitride layer or the polysilicon layer by a dry etching method having excellent vertical etching characteristics. Here, if the spacer 24 includes a silicon nitride layer, the distance between the sidewall of the write word line 30 and the flip electrode 50 can be constantly maintained.

On the other hand, when the spacer 24 is formed of a polysilicon layer, it can be removed together with the first sacrificial layer 60 to form a vacant space. Then, when the spacer 24 is formed of the polysilicon layer, it can be formed by the same process as that of the first sacrificial layer 60 after the first interlayer insulating layer 22 and the write word line 30 are formed. For example, the first interlayer insulating layer 22 and the write word line 30 crossing the bit line 20 are formed on the bit line 20, and a polysilicon layer is formed on the entire surface of the substrate 30 where the first interlayer insulating layer 22 and the write word line 30 are formed. The spacer can be formed by patterning the polysilicon layer while being connected to the first sacrificial layer 60 and surrounding the sidewalls of the first interlayer insulating layer 22 and the write word line 30.

Although not illustrated, when the bit line 20 is formed, a first hard mask layer formed on the bit line 20 can be removed by the reaction gas used by a dry etching method when the spacer 24 is formed. Therefore, the bit line 20 can be exposed when the spacer 24 is formed.

As shown in FIG. 5D and 6D, a dimple 100a or a groove which is a recessed portion of a central portion of the first sacrificial layer 60 is formed by removing the first sacrificial layer 60 lengthwise by a predetermined depth at an upper central portion of the write word line 30. For example, the dimple 100a or the groove can be formed by removing the first sacrificial layer 60 by a predetermined depth by a wet etching method or a dry etching method using a photoresist pattern or a second hard mask layer exposing an upper central portion of the first sacrificial layer 60 as an etch mask. Here, the dimple 100a or the groove can form a contact part 100 electrically connected to the distal end of the flip electrode 50 formed in a subsequent process and making an electrical contact with the write word line 30 under a predetermined condition after the first sacrificial layer 60 is removed. Then, the dimple 100a or the groove has a width greater than that of the trench 90 formed to remove the first sacrificial layer 60 in the following process. Therefore, the dimple 100a or the groove formed by removing the center of the first sacrificial layer 60 can reduce the distance between the contact part 100 and the write word line 30 if a vacant space is formed after the first sacrificial layer 60 is removed in a subsequent process.

As illustrated in FIGS. 5E and 6E, the flip electrode 50 and the contact part 100 are formed crossing an upper portion of the stack including the first sacrificial layer 60, the write word line 30, and the first interlayer insulating layer 22, and the dimple 100a or the groove and are electrically connected to the bit line adjacent to the spacer 24 on the side surfaces of the stack. Here, the flip electrode 50 is formed to cover the stack and to be electrically connected to the bit line 20 formed on both sides of the stack. The flip electrode 50 has a line width equal to or similar to that of the bit line 20, and is stacked to cover the spacers at both sides of the stack. Further, the contact part 100 is formed to bury the interior of the dimple 100a or the groove recessed in the direction of the write word line 30 at the center of the flip electrode 50. Then, the contact part 100 is thicker than the flip electrode 50.

For example, the flip electrode 50 and the contact part 100 can be formed by forming a conductive metal layer, such as titanium and titanium silicide or a carbon nano tube having a predetermined thickness, on the entire surface of the substrate 10 in which the stack and the spacer 24 are formed, by forming a photoresist pattern or a third hard mask layer shielding the conductive metal layer or the carbon nano tube on the bit line 20, and by anisotropically etching the conductive metal layer or the carbon nano tube by a dry etching method using the photoresist pattern or the third hard mask layer as an etch mask. Then, the conductive metal layer can be formed by a physical vapor deposition method or a chemical vapor deposition method and the carbon nano tube can be formed by an electric discharge method. Further, the third hard mask layer can be removed when the flip electrode 50 is patterned or can be left on the flip electrode 50.

Therefore, in the method for manufacturing the memory device according to the first embodiment, the distance between the contact part 100 and the write word line 30 can be reduced to be smaller than the distance between the flip electrode 50 and the write word line 30 by forming the contact part 100 protruding in the direction of the write word line 30 from a central portion of the flip electrode 50 formed over the write word line 30 insulated from the bit line 20 and crossing the bit line 20.

As illustrated in FIGS. 5F and 6F, the second interlayer insulating layer 26 having a predetermined thickness is formed on the entire surface of the substrate 10 in which the flip electrode 50 and the contact part 100 are formed. The second interlayer insulating layer 26 is then removed and planarized to expose the flip electrode 50 and the contact part 100. Here, the second interlayer insulating layer 26 provides a planarized surface so that the second sacrificial layer 70 and the read word line 40 (see FIG. 5G) can be formed in a direction parallel to the write word line 30 and the first sacrificial layer 60 on the write word line 30 having a portion stepped from the substrate 10 and the flip electrode 50 on the first sacrificial layer 60.

Further, with the second interlayer insulating layer 26, patterning processes of the flip electrode 50 and the contact part 110 under the second interlayer insulating layer 26 and the read word line 40 can be performed separately. This is because the flip electrode 50, the contact part 100, and the read word line 40 include excellent conductive metal layers and the etch selectivity of almost all etching solutions or reaction gases used to pattern the conductive metal layer is relatively low. Therefore, the second interlayer insulating layer 26 is inevitably used in a process of separating and forming two stacked lines or patterns including a conductive metal layer. For example, the second interlayer insulating layer 26 can be formed of a silicon oxide layer formed by TEOS, USG, and HDP chemical vapor deposition method.

Then, the second interlayer insulating layer 26 is formed on the entire surface of the substrate 10 in which the flip electrode 50, the contact part 100, and the third hard mask layer are formed, so that the second interlayer insulating layer 26 has a height greater than that of the flip electrode 50. Further, the second interlayer insulating layer 26 can be planarized by a chemical mechanical polishing method to expose the flip electrode 50 and the contact part 100 on the first sacrificial layer 60.

Therefore, the method for manufacturing the memory device according to the first embodiment includes forming the second interlayer insulating layer 26 on the entire surface of the substrate 10 on which the flip electrode 50 and the contact part 100 have been formed, and planarizing the second interlayer insulating layer 26 to expose the flip electrode 50 and the contact part 100 formed on the write word line 30 and the first sacrificial layer 60, so that a second sacrificial layer 70 and a read word line 40 can be patterned in a subsequent process.

As illustrated in FIGS. 5G and 6G, the second sacrificial layer 70 and the read word line 40 are formed in a direction parallel to the first sacrificial layer 60 and the write word line 30 on the flip electrode 50 and the contact part 100 exposed by the second interlayer insulating layer 26. Here, the second sacrificial layer 70 and the read word line 40 are formed symmetrically with respect to the first sacrificial layer 60 and the write word line 30 about the flip electrode 50. For example, like the first sacrificial layer 60, the second sacrificial layer 70 can be composed of a polysilicon material formed by an atomic layer deposition method or a chemical vapor deposition method and has a thickness of approximately 50 Å to 150 Å. Further, the read word line 40 has a thickness of approximately 200 Å and has a line width of approximately 30 Å to 1000 Å. Then, the second sacrificial layer 70 and the read word line 40 can be formed in the following way. First, the polysilicon layer, the conductive metal layer, and the fourth hard mask layer 42 having predetermined thicknesses are stacked on the second interlayer insulating layer 26 by a chemical vapor deposition method. Next, the photoresist pattern shielding the fourth hard mask layer 42 on the first sacrificial layer 60 Is and the write word line 30 is formed, and after the fourth hard mask layer 42 is removed by a dry etching method or wet etching method using the photoresist pattern as an etch mask, the photoresist pattern is removed by an ashing process. Finally, the second sacrificial layer 70 and the read word line 40 can be formed by anisotropically etching the polysilicon layer and the conductive metal layer by a dry etching method and wet 20 etching method using the fourth hard mask layer 42 as the etch mask.

As illustrated in FIGS. 5H and 6H, the fourth hard mask layer 42 formed on the read word line 40 is reduced and patterned to a predetermined line width. Here, the patterned fourth hard mask layer 42 defines the line width of the trench in a subsequent process. For example, the fourth hard mask layer 42 is anisotropically etched by a dry etching method or a wet etching method using a photoresist pattern shielding the lengthwise center of the read word line 40 formed in one direction as an etch mask to reduce the line width. Then, the fourth hard mask layer 42 has a width smaller than that of the contact part 100. Further, the fourth hard mask layer 42 can be isotropically etched by a dry etching method or a wet etching method having excellent etching characteristics in a side surface direction, rather than in a plan surface direction, to reduce the line width. The reaction gas or the etching solution used in an isotropic dry etching method or a wet etching method can selectively etch a side surface of the fourth hard mask layer 42 while flowing in a direction parallel to the substrate 10.

As illustrated in FIGS. 5I and 6I, the third interlayer insulating layer 28 of a predetermined thickness is formed on the fourth hard mask layer 42 having a reduced line width and the third interlayer insulating layer 28 is planarized to expose the fourth hard mask layer 42. Here, the third interlayer insulating layer 28 has a thickness greater than those of the second sacrificial layer 70 and the read word line 40. Therefore, if the second sacrificial layer 70 is removed in a subsequent process, the third interlayer insulating layer 28 supports a side surface of the read word line 40 and floats the read word line 40 from the flip electrode 50. For example, the third interlayer insulating layer 28 includes a silicon oxide layer formed by a TEOS, USG, or HDP chemical vapor deposition method, as examples. Further, the third interlayer insulating layer 28 can be planarized by a chemical mechanical polishing method. Then, if the third interlayer insulating layer 28 is planarized using the read word line 40 as an etch stop layer, since the read word line 40 including a conductive metal layer can be damaged, the fourth hard mask layer 42 should be used as an etch stop layer.

As illustrated in FIGS. 5J and 6J, the trench 90 in which the first interlayer insulating layer 22 is exposed from the bottom is formed by anisotropically etching the fourth hard mask layer 42, the read word line 40, the second sacrificial layer 70, the contact part 100, the first sacrificial layer 60, and the write word line 30 sequentially using a dry etching method with the third interlayer insulating layer 28 used as an etch mask. Here, the trench 90 separates symmetrically and plurally the read word line 40, the second sacrificial layer 70, the contact part 100, the flip electrode 50, the first sacrificial layer 60, and the write word line 30. The trench 90 can be formed by a dry etching method using a reaction gas having a high etch selectivity with respect to the polysilicon and the conductive metal layer as compared to the third interlayer insulating layer 28, including a silicon oxide layer, and the first interlayer insulating layer 22.

For example, the reaction gas used in the dry etching method can be one or more carbon fluoride gas chosen from a group of carbon fluoride gases, such as a CxFy gas or a CaHbFc gas. The carbon fluoride gas can include CF₄, CHF₃, C₂F₆, C₄F₈, CH₂F₂, CH₃F, CH₄, C₂H₂, and C₄F₆ or a mixture gas thereof. If the width of the trench 90 is reduced, interference can be generated between the write word line 30, the read word line 40, and the flip electrode 50, which are adjacent to each other. Further, the etching solution or the reaction gas etching the first sacrificial layer 60 and the second sacrificial layer 70 through the trench 90 in a subsequent process cannot be normally flowed.

On the other hand, if the width of the trench 90 becomes wider, the integration of a unit device is reduced but the etching solution or the reaction gas etching the first sacrificial layer 60 and the second sacrificial layer 70 can be flowed smoothly. Therefore, the trench 90 symmetrically separates the write word line 30, the contact part 100, the flip electrode 50, and the read word line 40 and has a line width capable of normally flowing the etching solution or the reaction gas to remove the first sacrificial layer 60 between the write word line 30 and the flip electrode 50 and the second sacrificial layer 70 between the contact part 100 and the flip electrode 50 and the read word line 40. For example, the trench 90 has a line width of approximately 30 Å to 800 Å, which gives the trench 90 a smaller line width than the contact part 100.

Although not illustrated, if the process of reducing the line width of the fourth hard mask layer 42 is eliminated, the fourth hard mask layer 42, the read word line 40, the second sacrificial layer 70, the flip electrode 50, the first sacrificial layer 60, and the write word line 30 are anisotropically etched sequentially to form the trench 90 by a dry etching method using a photoresist pattern exposing the third interlayer insulating layer 28 formed at the lengthwise center of the read word line 40 and the write word line 30 as an etch mask.

As illustrated in FIGS. 5K and 6K, the first sacrificial layer 60 and the second sacrificial layer 70 exposed by the trench 90 are removed, thereby forming a vacant space so that the flip electrode 50 and the contact part 100 are floated between the write word line 30 and the read word line 40. For example, the first sacrificial layer 60 and the second sacrificial layer 70 can be isotropically etched from an exposed surface in the sidewall of the trench 90 by a wet etching method or a dry etching method to be removed. The etching solution used in the wet etching method of the first sacrificial layer 60 and the second sacrificial layer 70 formed of a polysilicon material can be a mixture solution in which a strong acid, such as nitric acid, hydrofluoric acid, acetic acid, is mixed with deionized water at a predetermined concentration. The etching solution or the reaction gas used in the wet etching method or the dry etching method removes the first sacrificial layer 60 and the second sacrificial layer 70 exposed from a sidewall of the trench 90 in a transverse direction, thereby forming a vacant space between the read word line 40 and the write word line 30.

When the spacer 24 is composed of a polysilicon material, the spacer 24 can also be etched by the etching solution or the reaction gas to form a vacant space. Then, if the distance of the vacant space formed by removing the spacer 24 is significantly smaller than the distance of a vacant space between the write word line 30 and the contact part 100, not the contact part 100, but rather a portion of the flip electrode 50 on the side of a side surface of the write word line 30 can make electrical contact with the write word line 30, causing failure in writing and reading information. Therefore, when the spacer 24 is removed, the distance between the write word line 30 and the contact part 100 becomes larger than the distance between the side surface of the write word line 30 and the flip electrode 50.

Although not illustrated, the interior of the trench 90 is sealed by forming the fourth interlayer insulating layer 110 covering the upper end of the trench 90. Then, the vacant space in the interior of the trench 90 can be filled with nitrogen or argon in the air and a non-reaction gas, and can also be set in a vacuum state to increase the bending speed of the flip electrode 50. Further, bit line 20, write word line 30, contact part 100, flip electrode 50, and read word line 40 can be sequentially formed at the upper end of the substrate 10 in which the fourth interlayer insulating layer 110 is formed, thereby resulting in the manufacture of a memory device having a multi-layer structure.

Therefore, in the method for manufacturing the memory device according to the first embodiment, a plurality of write word lines 30, a plurality of flip electrodes 50, a plurality of contact parts 100, and a plurality of read word lines 40 are symmetrically formed using the trench 90 formed in one direction crossing the bit line 20 formed on the substrate 10, thereby improving the integration of the memory device.

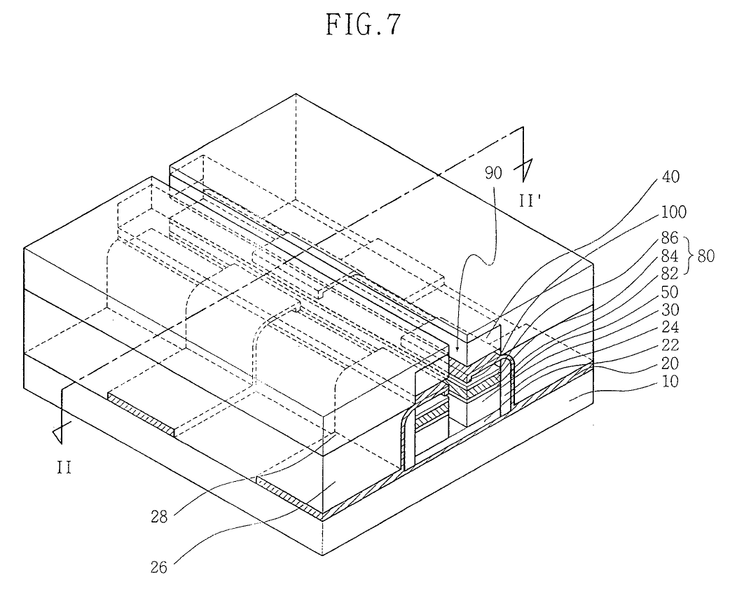

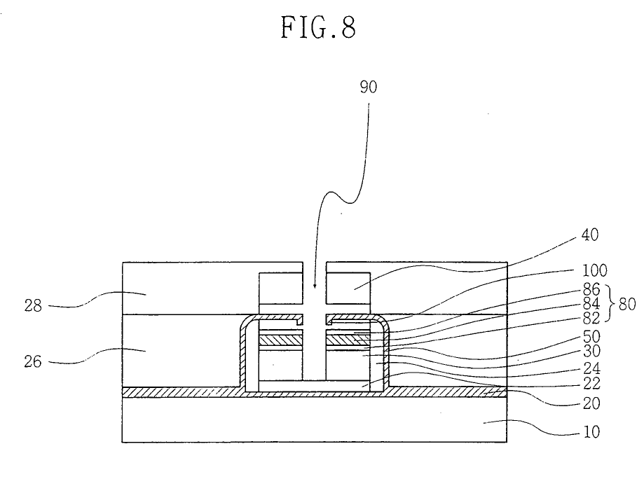

FIG. 7 is a perspective view illustrating second embodiment of a memory device according to an aspect of the present invention. FIG. 8 is a cross-sectional view taken along the line II-II′ of FIG. 7. When the names of elements illustrated in the second embodiment are same as those of the first embodiment, the elements of the second embodiment will be referred to as the same names as used in the first embodiment.

As illustrated in FIGS. 7 and 8, the memory device according to the second embodiment includes a substrate 10 having a flat surface, a bit line 20 formed on the substrate 10 in one direction, a write word line (e.g. a first word line) 30 and a read word line (e.g. a second word line) 40 provided above the bit line 20, while insulated from and crossing the bit line 20, having a vacant space therebetween, and being parallel to each other, a flip electrode 50 electrically connected to the bit line 20 and formed over the write word line 30 above the bit line 20 and configured to be bent in one direction by electric fields induced between the write word line 30 and the read word line 40, a contact part 100 concentrating charges induced by the flip electrode 50 in response to charges applied by the write word line 30 between the flip electrode 50 and the bit line 20 and protruding from the lower end of the flip electrode 50 by a predetermined thickness in the direction of the write word line 30 to reduce the length by which the flip electrode 50 is bent, and a trap site 80 formed between the contact part 100 and the write word line 30 so as to be insulated from the contact part 100 and the write word line 30 and trapping charges applied from the write word line 30 or from outside to electrostatically fix the contact part 100 and the flip electrode 50 bent in the direction of the write word line 30.

Here, the substrate 10 provides a flat surface so that the bit line 20 can be formed in one direction. For example, the substrate 10 includes an insulating substrate or a semiconductor substrate having an excellent flexibility so that the substrate 10 can be bent by an external force.

The bit line 20 is formed on the substrate 10 along one direction at a predetermined thickness. Further, the bit line 20 is composed of a material having an excellent electrical conductivity. For example, the bit line 20 can be composed of a conductive metal material such as gold, silver, copper, aluminum, tungsten, tungsten silicide, titanium, titanium nitride, tantalum, and tantalum silicide or a silicon or polysilicon material doped with conductive impurities. Although not illustrated, a first hard mask layer used to pattern the bit line 20 including the conductive metal material or the polysilicon material can have a line width equal to or similar to that of the bit line 20 between the write word line 30 and the bit line 20.

The write word line 30 crosses the bit line 20 above the substrate 10 and is insulated from the bit line 20. Similarly, the write word line 30 can be composed of a conductive metal material such as gold, silver, copper, aluminum, tungsten, tungsten silicide, titanium, titanium nitride, tantalum, and tantalum silicide. Then, the write word line 30 and the bit line 20 are separated from each other, with a first interlayer insulating layer 22 having a predetermined thickness being interposed between the write word line 30 and the bit line 20, to decrease the interference therebetween. The first interlayer insulating layer 22 has the same direction as the write word line 30. This is because the bit line 20 should be exposed on a side surface of the write word line 30 during the formation of the flip electrode 50 in order to bring the flip electrode 50 formed above the write word line 30 into contact with the bit line 20. Further, the first interlayer insulating layer 22 can be used as an etch stop layer during the formation of a trench 90 symmetrically separating a plurality of write word lines 30, a plurality of flip electrodes 50, and a plurality of read word lines above the bit line 20. For example, the first interlayer insulating layer 22 can include a silicon oxide layer, a silicon nitride layer, and a silicon oxynitride layer. Therefore, the write word line 30 is insulated by the first interlayer insulating layer 22 on the bit line 20 formed on the substrate 10 in one direction and crosses the bit line 20. Further, a plurality of write word lines 30 are separated in parallel to each other by the trench 90 formed on the first interlayer insulating layer 22 crossing the bit line 20.

The trap site 80 is stacked on the write word line 30 in a same or similar direction and has a line width equal to or similar to that of the write word line 30. For example, like the write word line 30, a plurality of layers forming the trap site 80 are separated in parallel to each other by the trench 90 formed on the first interlayer insulating layer 22. Further, the trap site 80 traps the charges applied through the write word line 30 by tunneling the charges into the interior of a predetermined thin film, and always restricts the trapped charge even when no charge is supplied from outside. For example, the trap site 80 includes a thin film having an oxide-nitride-oxide (ONO) structure in which a first silicon oxide layer 82 formed on the write word line 30, a silicon nitride layer 84, and a second silicon oxide layer 86 are stacked.

Further, the trap site further includes a thin film having a structure in which the first silicon oxide layer 82, the polysilicon layer, and the second silicon oxide layer 86 are stacked. The polysilicon layer is doped with conductive impurities and has conductivity. Then, the first silicon oxide layer 82 and the second silicon oxide layer 86 are insulating layers electrically insulating the silicon nitride layer 84 and the polysilicon layer between the write word line 30 and the flip electrode 50. Especially, the first silicon oxide layer 82 is a tunnel insulating layer selectively tunneling a charge according to the direction and the magnitude of an electric field applied between the silicon nitride layer 84 or the polysilicon layer and the write word line 30.

For example, the silicon nitride layer 84 and the polysilicon layer are electrically separated by the first silicon oxide layer 82 and the second silicon oxide layer 86 and can be referred to as a floating electrode introducing and discharging a charge through the first silicon oxide layer under a condition of a predetermined voltage or higher.

Therefore, the memory device according to the second embodiment of the present invention includes the trap site 80 trapping the charges applied through the write word line 30 by tunneling the charges and restricting the trapped charges even when the charges applied to the write word line 30 are removed. Thus, since the contact part 100 and the flip electrode 50 maintain the state that they are deflected toward the direction word line 30 using the charges restricted by the trap site 80, a nonvolatile memory can be made.

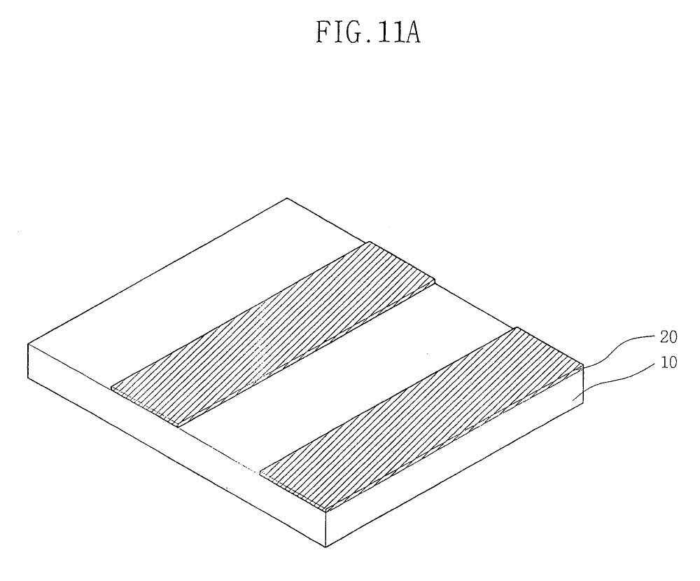

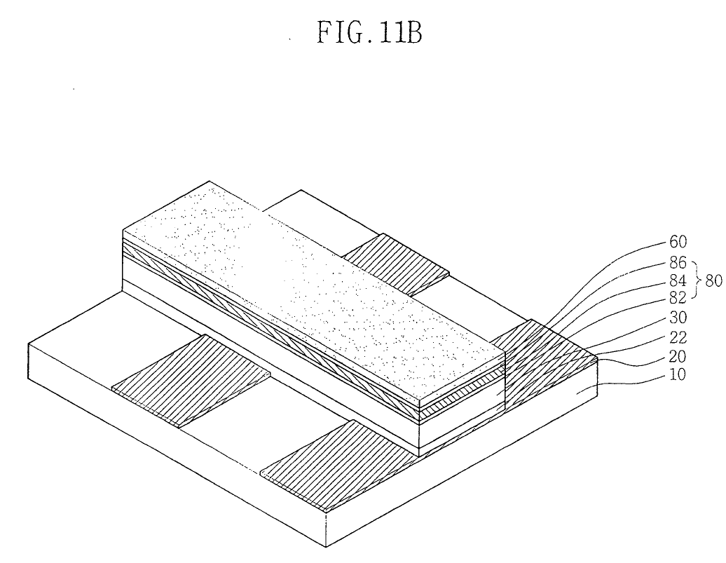

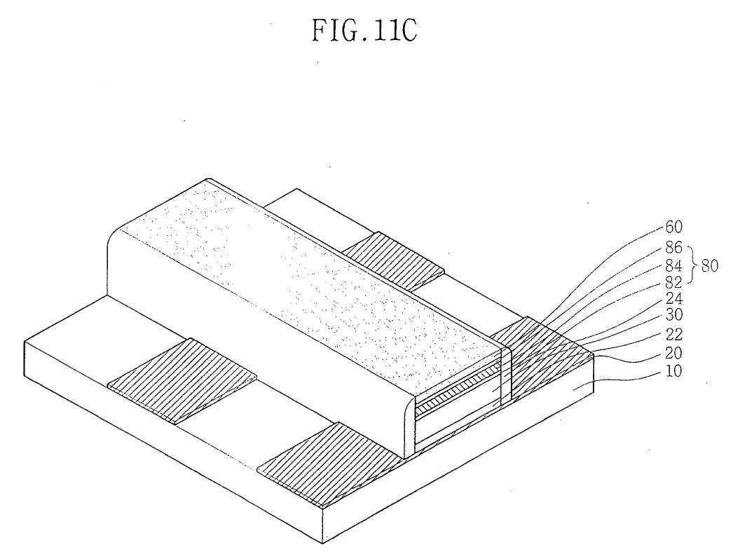

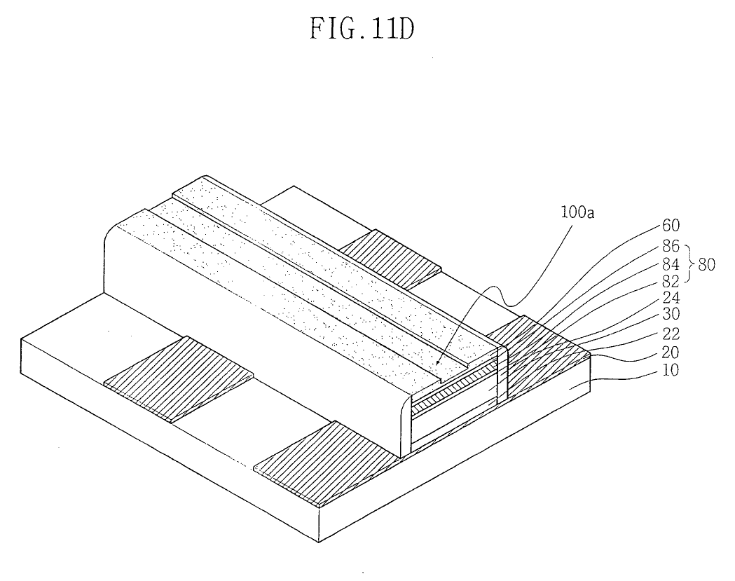

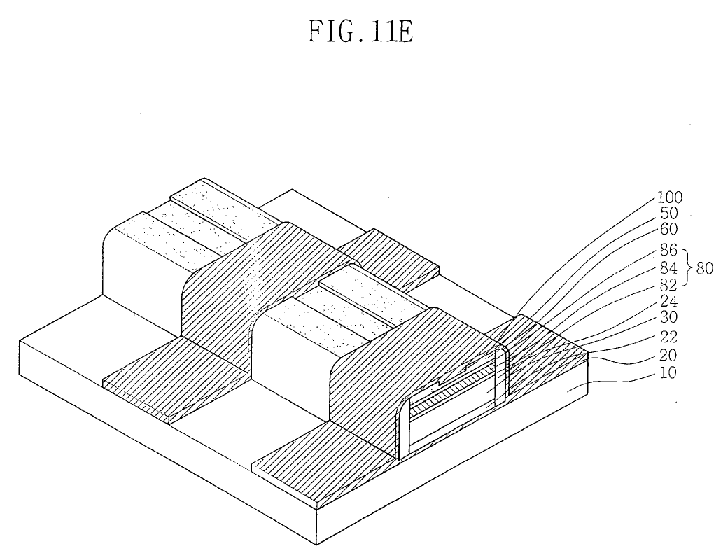

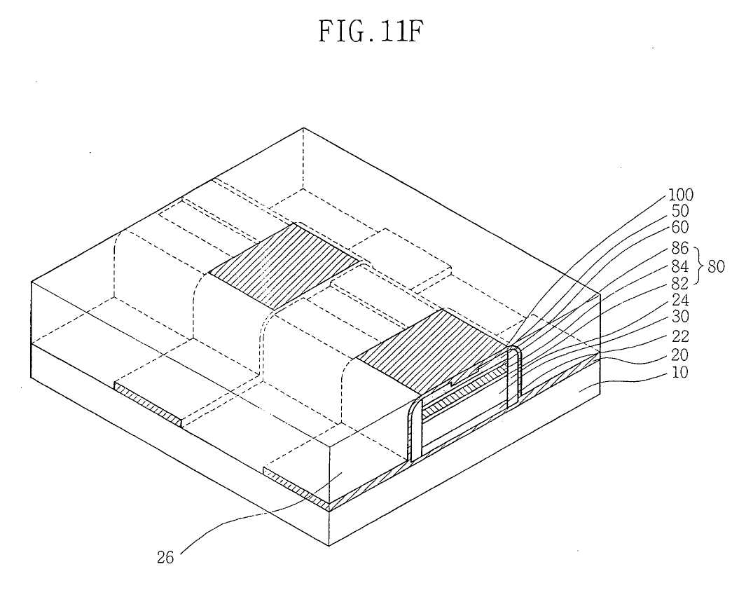

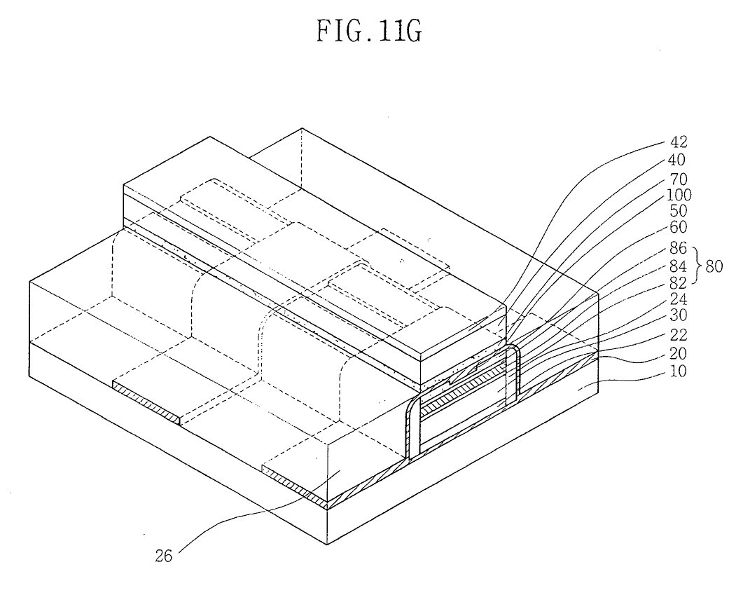

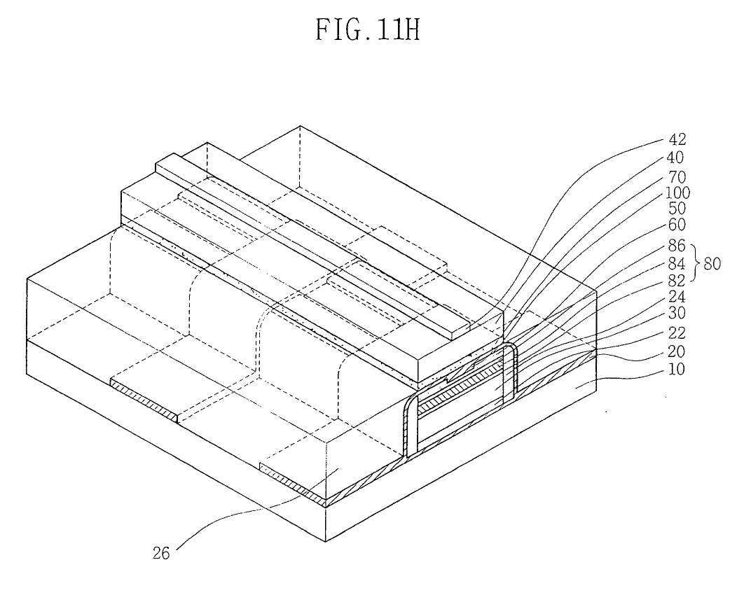

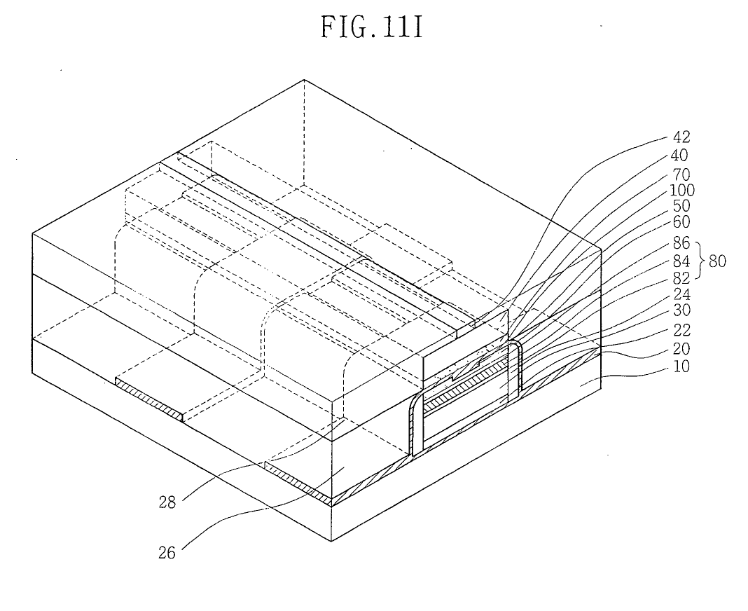

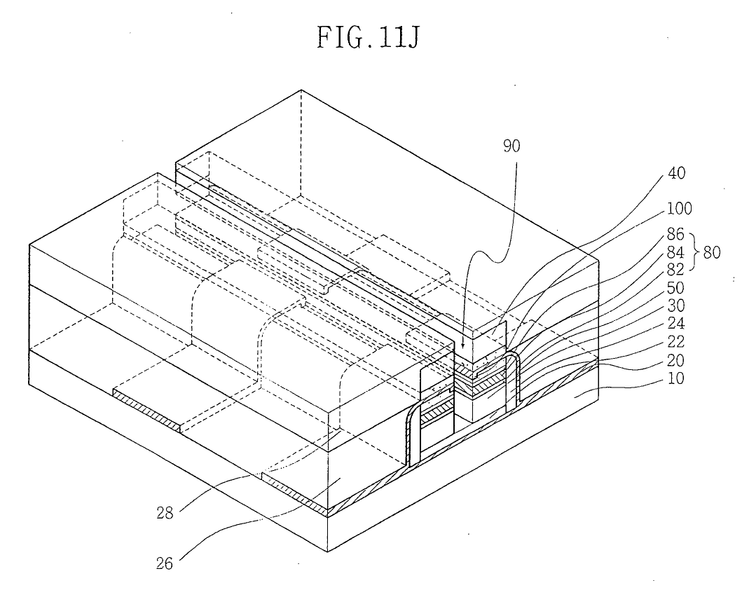

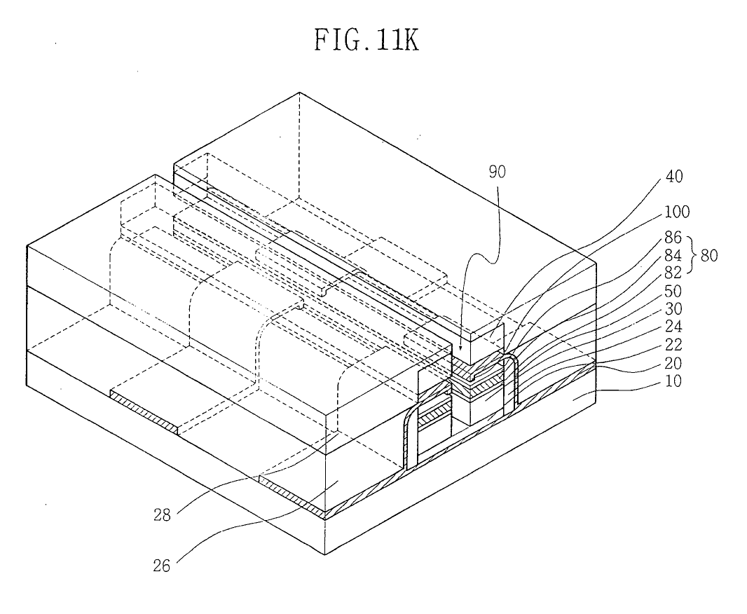

Although not illustrated, the memory device according to the second embodiment includes the first sacrificial layer 60 (FIG. 11B) stacked on the write word line 30 and the trap site 80 and removed so that the flip electrode 50 and the contact part 100 are separated from the write word line 30 by a predetermined distance and vacant spaces are formed between the flip electrode 50 and the contact part 100 and the trap site 80 through the trench 90. Here, the first sacrificial layer 60 is formed on the trap site 80 and has a predetermined thickness. Further, the first sacrificial layer 60 has a line width equal to or similar to those of the write word line 30 and the trap site 80. The first sacrificial layer 60 is removed by an etching solution or a reaction gas which is introduced through the trench 90, exposing the first interlayer insulating layer 22, in the direction of the write word line 30 and the trap site 80 and has an excellent etch selectivity. For example, the first sacrificial layer 60 can be composed of a polysilicon material. Therefore, the first sacrificial layer is formed to define the vacant space to which the flip electrode 50 is bent. Further, the contact part 100 is defined by the dimple 100a or the groove formed by recessing the center of the first sacrificial layer 60 by a predetermined depth in the direction of the write word line 30.

A spacer 24 is formed between a side surface of the stack including the first interlayer insulating layer 22, the write word line 30, the trap site 80, and the first sacrificial layer 60, and the flip electrode 50. Here, the spacer 24 separates the flip electrode 50 from sidewalls of the write word line 30 and the trap site 80 by a predetermined distance. The spacer 24 has a height corresponding to an edge of the upper end of a vacant space formed between the flip electrode 50 and the write word line 30 and the trap site 80 or an edge of the upper end of the sacrificial layer 60 and surrounds a side surface of the stack. For example, the spacer 24 can be composed of the same insulation material as a silicon nitride layer. Further, if the spacer 24 is composed of a polysilicon material like the first sacrifical layer 60, it can be removed together with the first sacrificial layer 60 by an etching solution or a reaction gas showing the same or similar etch selectivity with respect to the first sacrificial layer 60, to form the vacant space between the sidewall of the stack and the flip electrode 50.

The flip electrode 50 is electrically connected to the bit line 20 adjacent to the spacer 24 and extends to the upper side of the first sacrificial layer 60 and the trap site 80 along the side surface of the spacer 24. Further, the flip electrode 50 has a line width equal to or similar to the bit line 20 and is formed in the direction of the bit line 20. The flip electrode 50 is formed over the first interlayer insulating layer 22, the write word line 30, and the trap site 80 crossing the bit line 20. Then, a plurality of flip electrodes 50 and a plurality of contact parts 100 are symmetrically separated on both sides about the trench 90 symmetrically separating a plurality of write word lines 30. The flip electrode 50 is formed of a conductive material having a predetermined elasticity to be bent along the contact part 100 moved upward and downward by an electric field induced in the vacant space formed between the write word line 30 and the read word line 40. For example, the flip electrode 50 can be composed of titanium, a titanium nitride layer, or a carbon nano tube material.

Then, the carbon nano tube forms a pipe shape by connecting hexagonal shapes including six carbon atoms. The name of carbon nano tube comes from the diameter of the pipe being merely several to tens of nanometers. The electric conductivity of the carbon nano tube is similar to that of copper and the thermal conductivity of the carbon nano tube is substantially the same as that of a diamond, which is most excellent in the nature. Further, the strength of the carbon nano tube is about 100 times stronger than steel. The carbon nano tube has a restoring force high enough to be suitable for about fifteen percent of deformation, while a carbon fiber is broken by one percent of deformation.

As mentioned above, the flip electrode 50 is bent upward and downward above the write word line 30. The inner surface of the flip electrode 50 is fixed by the spacer 24 formed on a side surface of the write word line 30. Further, if the spacer 24 is not provided and a vacant space is formed on the sidewall of the stack, the flip electrode 50 can be fixed by the second interlayer insulating layer 26 on the outer side of the flip electrode 50. Here, the second interlayer insulating layer 26 has a height equal to or similar to the flip electrode 50. Although not shown, the second interlayer insulating layer 26 can have a height equal to or similar to that of a third hard mask layer formed on the flip electrode 50 to pattern the flip electrode 50. For example, the second interlayer insulating layer 26 can be formed of a silicon oxide layer material. Then, the second interlayer insulating layer 26 has a flat surface together with the flip electrode 50 or the third hard mask layer on the flip electrode 50 so as to pattern a second sacrificial layer 70 and the read word line 40.

The contact part 100 protrudes in the direction of the write word line 30 and the trap site 80 from the distal end of the flip electrode 50 above the write word line 30 crossing the bit line 20. For example, the contact part 100 can be formed together with the flip electrode 50 by the dimple 100a or the groove in which the center of the first sacrificial layer 60 formed on the write word line 30 is recessed by a predetermined depth. Although not shown, the contact part 100 can be formed by filling the same conductive metal material as the flip electrode 50 in the dimple 100a or the groove removed by a predetermined depth isotropically or anisotropically using a wet etching method or a dry etching method that uses a second hard mask layer exposing a central upper portion of the first sacrificial layer 60 as an etch mask. Therefore, the contact part 100 protrudes from the most distal end of the flip electrode 50 in the direction of the write word line 30.

Further, if the first sacrificial layer 60 is removed, the flip electrode 50 and the contact part 100 can be floated by predetermined heights with respect to the write word line 30. Therefore, the contact part 100 is formed to reduce the bent distance of the flip electrode 50 when it is bent in the direction of the write word line 30 under a predetermined condition. The bent distance of the flip electrode 50 can be reduced in correspondence to the thickness of the contact part 100. If charges of different polarities are applied to the write word line 30 and the trap site 80 and the flip electrode 50 at a predetermined voltage, the flip electrode 50 can be bent in the direction of the write word line 30. Then, the charges applied through the flip electrode 50 can be concentrated in the contact part 100. For example, since the charges applied to the flip electrode 50 are concentrated in the contact part 100 by Gauss's law, an attraction force is applied to the contact part 100 in the direction of the write word line 30 and the trap site 80 to bend the flip electrode 50. The relations between the electric field and the voltage induced between the contact part 100 and the write word line 30 and the movement of the contact part 100 will be described later.

Although not illustrated, the memory device according to the second embodiment further includes a second sacrificial layer 70 formed on the flip electrode 50 to separate the read word line 40 from the flip electrode 50 by a predetermined distance and removed to the sidewall exposed by the trench 90 so that a vacant space is formed between the flip electrode 50 and the read word line 40. Here, like the first sacrificial layer 60, the second sacrificial layer 70 can be isotropically etched by an etching solution or a reaction gas introduced into the interior of the trench 90 to be removed. For example, the second sacrificial layer 70 defines the distance by which the flip electrode 50 is bent in the direction of the read word line 40 and can be composed of a polysilicon material like the first sacrificial layer 60.

Further, the read word line 40 is stacked on the second sacrificial layer 70 and has a line width equal to or similar to that of the second sacrificial layer 70. For example, the read word line 40 can be composed of a conductive metal material, such as gold, silver, copper, aluminum, tungsten, tungsten silicide, titanium, titanium nitride, tantalum, and tantalum silicide. The read word line 40 has a vacant space above the flip electrode 50. Therefore, a third interlayer insulating layer 28 is formed to support a side surface of the read word line 40 on the second interlayer insulating layer 26 in order to float the read word line 40 above the flip electrode 50 if the second sacrificial layer 70 on the flip electrode 50 is removed and a vacant space is formed. Here, the third interlayer insulating layer 28 can form a plurality of read word lines 40, a plurality of flip electrodes 50, a plurality of contact parts 100, and a plurality of write word lines 30 as a mask layer symmetrically formed about the trench 90 when the trench 90 is formed. Then, the third interlayer insulating layer 28 is planarized to form a photoresist pattern opening a fourth hard mask layer 42 on the read word line 40. Further, the third interlayer insulating layer 28 is planarized to form a photoresist pattern opening an upper portion corresponding to the fourth hard mask layer 42 formed on the read word line 40.

The trench 90 can symmetrically form a plurality of read word lines 40, a plurality of flip electrodes 50, a plurality of trap sites 80, and a plurality of write word lines 30, respectively, by separating the read word line 40, the flip electrode 50, the contact part 100, the trap site 80, and the write word line 30. For example, the trench 90 can have a direction equal to or similar to those of the write word line 30, the trap site 80, and the read word line 40 and can separate the flip electrode 50 and the contact part 100 symmetrically while crossing the flip electrode 50, the contact part 100, and the bit line 20.

Therefore, the integration of a unit device is increased, since the memory device according to the second embodiment includes the trench 90 separating the read word line 40 having a vacant space, the trap site 80, and the write word line 30 to both sides of trench 90 in the lengthwise direction and separating the contact part 100 and the flip electrode 50, the contact part 100 electrically connected to the bit line 20 below the write word line 30 so that the distances between a plurality of lines having a symmetrical structure about the trench 90 are reduced.

Meanwhile, the write word line 30 and the read word line 40 can be replaced by a lower electrode and an upper electrode for inducing an electric field by charges from outside, or external to the device. As mentioned above, the trap site 80 traps charges applied through the write word line 30 by tunneling the charges and maintains the trapped state of the charges even when the charges are removed from the write word line 30. Therefore, the memory device according to the second embodiment can write and read information corresponding to a direction in which the flip electrode 50 and the contact part 100 formed in the vacant space between the trap site 80 and the read word line 40 are bent toward the trap site 80 and the read word line 40.

Hereinafter, the writing and reading process of the information corresponding to the bending direction of the flip electrode 50 and the contact part 100 will be described. It will be described how the bending direction of the flip electrode 50 and the contact part 100 are varied by an electric field induced by the charges applied through the flip electrode 50, the bit line 20, the write word line 30, the trap site 80, the contact part 100, and the write word line 40. And the detailed relation of the voltages to be applied to the bit line 20, the write word line 30, and the write word line 40 will be described.

First, when charges having a voltage of a predetermined level are applied to the write word line 30, the charges are tunneled through the first silicon oxide layer 82 and are trapped by the silicon nitride layer 84 and the polysilicon layer. Further, when charges having a polarity opposite to the charges trapped by the trap site 80 are supplied to the contact part 100 on the trap site 80, the contact part 100 is moved in the direction of the trap site 80. On the other hand, when charges having a same polarity as that of the charges trapped by the trap site 80 are supplied to the contact part 100, the contact part 100 is moved to the read word line 40 above the trap site 80. Here, the movement direction of the contact part 100 can be represented by the Coulombic force of Formula 1 above.

According to the Coulombic force, when the charges applied to the contact part 100 and the charges applied to the write word line 30 and the trap site 80 have the same polarity, the contact part 100 can become remote from the write word line 30 and the trap site 80 by a repulsive force. The contact part 100 can be moved in the direction of the read word line 40 by applying charges having a polarity opposite to that of the charges applied to the contact part 100 from the read word line 40 formed on the upper side of the contact part 100 corresponding to the write word line 30 and the trap site 80.

Meanwhile, when the charges applied to the contact part 100 and the charges applied to the write word line 30 and the trap site 80 have the opposite polarities, the contact part 100 can become close to the write word line 30 and the trap site 80 by an attractive force between the contact part, and the write word line 30 and the trap site 80. Therefore, when the charges of the opposite polarities are applied to the trap site 80 and the contact part 100, the contact part 100 can be moved in the direction of the trap site 80. The contact part 100 can be moved in the direction of the trap site 80 by applying charges of the same polarity as that of the charges supplied from the contact part 100 to the read word line 40.

Then, as the distance between the contact part 100 and the trap site 80 decreases, the Coulombic force applied between the contact part 100 and the trap site 80 increases. Therefore, as the Coulombic force increases, the flip electrode 50 is increasingly bent in the direction of the trap site 80. Similarly, as the distance between the contact part 100 and the trap site 80 decreases, the voltage applied between the contact part 100, and the trap site 80 and the write word line 30 also decreases.

Therefore, the power consumption can be reduced, since the memory device according to the second embodiment includes the contact part 100 protruding in the direction of the write word line 30 from the distal end of the flip electrode 50 bent in the direction of the trap site 80 and the write word line 30 to reduce the bent distance of the flip electrode 50 and can reduce the voltages applied to the contact part 100, the trap site 80, and the write word line 30 to bring the contact part 100 into contact with the trap site 80.

Meanwhile, when the flip electrode 50 is bent in the direction of the trap site 80 and the contact part 100 makes contact with or becomes close to the trap site 80, the distance between the trap site 80 and the flip electrode 50 is reduced and the Coulombic force applied as an attractive force is increased. This is because the Coulombic force increases in inverse proportion to the square of the distance between the trap site 80 and the flip electrode 50. Then, even if charges are not applied to the write word line 30 under the trap site 80, a predetermined amount of charges or more are restricted in the trap site 80. Further, even if charges are not applied to the bit line and the flip electrode 50, charges having a polarity opposite to that of the charges trapped by the trap site 80 are induced in the contact part 100 by the charges trapped by the trap site 80. This is because if the silicon nitride layer 84 and the contact part 100 on and under the second silicon oxide layer 86 are set to have a predetermined capacitance, with the second silicon oxide layer 86 of the trap site 80 being a dielectric, the contact part 100 and the second silicon oxide layer 86 can maintain a contact state even when the charges applied to the contact part 100 are removed. Therefore, the contact part 100 is brought into contact with the second silicon oxide layer 86 of the trap site 80 by the coupling charge induced from the charge trapped in the silicon nitride layer 84 of the trap site 80 and the flip electrode 50 can remain bent.

For example, since the electrostatic force represented by the Coulombic force is applied as strong as tens of thousands times a general elastic force or a restoring force, the electrostatic coupling between the trap site 80 and the contact part 100 is not broken by the elastic force or the restoring force of the flip electrode 50. Actually, in realizing a nano ultra-minute device with a scale of a micrometer or less, the Coulombic force has a magnitude proportional to the reciprocal of the square of a distance, but the elastic force or the restoring force has a magnitude simply proportional to a distance. Therefore, the contact part 100 having an ultra-minute structure can be moved in the direction of the trap site 80 by the Coulombic force, with the elastic force or the restoring force being neglected, or can be moved in the direction of the read word lne 40. Further, even if charges are not supplied to the write word line 30 and the contact part 100, charges having a polarity opposite to that of the charges of the trap site are induced in the contact part 100 by an electric field caused by the charges trapped in the trap site 80, and the trap site 80 and the contact part 100 remain close to each other to maintain the electric capacitance of a predetermined magnitude. Further, although a current of a predetermined magnitude or less is continuously supplied to the bit line 20, the contact part 100 is restricted by the electric field caused by the charges of the trap site 80 and continuously remains close to the trap site 80.

Therefore, the memory device according to the second embodiment can discriminate between a position potential at which the contact part 100 is close to or makes contact with the trap site 80 and a position potential at which the contact part 100 is separated from the trap site 80 to output information corresponding to one bit from the read word line 40. For example, information corresponding to a first potential (first voltage) proportional to the magnitude of the electric field induced between the read word line 40 and the contact part 100 close to or making contact with the trap site 80 and a second potential (second voltage) proportional to the magnitude of the electric field induced between the contact part 100 separated from and spaced apart from the trap site 80 and the read word line 40 can be output. Then, when predetermined information is to be read from the contact part 100 spaced apart from the trap site 80, an electrostatic attractive force is applied between the contact part 100 and the read word line 40 to move the contact part 100 in the direction of the read word line 40.

Therefore, since the memory device according to the second embodiment includes the trap site 80 trapping charges applied to the write word line 30 by tunneling the charges and continuing the contact state of the contact part 100 using the trapped charges to reduce the consumption of standby power to be applied to store predetermined information and the information can be prevented from being lost without charges supplied through the write word line 30, a nonvolatile memory device can be realized.

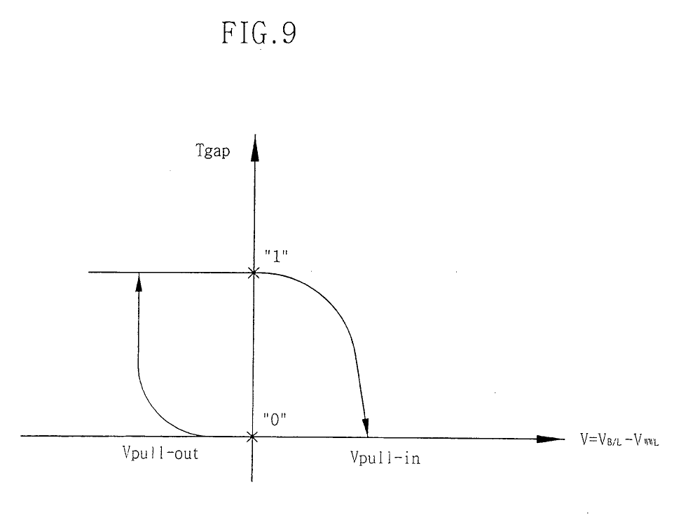

FIG. 9 is a graph representing a relationship between a voltage applied through the bit line 20 and the write word line 30, and a bending distance of the contact part 100 according to the second embodiment. If a voltage of ‘Vₚᵤₗₗ₋ᵢₙ’ having a positive value is applied between the bit line 20 and the write word line 30, the contact part 100 approaches the trap site 80 and information corresponding to ‘0’ is written. On the other hand, if a voltage of ‘Vₚᵤₗₗ₋ₒᵤₜ’ having a negative value is applied between the bit line 20 and the write word line 30, the contact part 100 becomes far away from the trap site 80 and information corresponding to ‘1’ is written.

Here, the transverse axis represents a level of the voltage and the longitudinal axis represents the distance T_{gap} by which the contact part 100 is moved from a surface of the trap site 80 to the read word line 40. Therefore, if the voltage of ‘Vₚᵤₗₗ₋ᵢₙ’ having a positive value or the voltage of ‘Vₚᵤₗₗ₋ₒᵤₜ’ having a negative value are applied to the contact part 100 connected between the bit line 20 and the write word line 30, the contact part 100 makes contact with or is separated from the trap site 80 and digital information corresponding to one bit having a value of ‘0’ or ‘1’ can be written.

Then, the voltage of ‘Vₚᵤₗₗ₋ᵢₙ’ and the voltage of ‘Vₚᵤₗₗ₋ₒᵤₜ’ can be determined by Formula 2.

V=V_{B/L}−V_{WWL} Formula 2:

Here, the ‘V’ represents the voltage of ‘Vₚᵤₗₗ₋ᵢₙ’ or ‘Vₚᵤₗₗ₋ₒᵤₜ’ VB/L is the voltage applied to the bit line 20 and ‘V_{WWL}’ is the voltage applied to the write word line 30. Then, the voltage of Vₚᵤₗₗ₋ᵢₙ has a positive value and the Vₚᵤₗₗ₋ₒᵤₜ has a negative value. Is For example, if the absolute values of the voltage of Vₚᵤₗₗ₋ᵢₙ and the voltage of Vₚᵤₗₗ₋ₒᵤₜ are same or similar, in the case in which information corresponding to the value of ‘0’ is to be recorded, the voltage of ½Vₚᵤₗₗ₋ᵢₙ is applied to the bit line 20 and the voltage of ½ Vₚᵤₗₗ₋ₒᵤₜ is applied to the write word line 30 to bring the contact part 100 into contact with the trap site 80.

Further, if the information corresponding to ‘1’ is to be written, the voltage of ½Vₚᵤₗₗ₋ₒᵤₜ is applied to the bit line 20 and the voltage of ½Vₚᵤₗₗ₋ᵢₙ is applied to the write word line 30 to separate the contact part 100 from the trap site 80. Although not illustrated, when the voltage of Vₚᵤₗₗ₋ᵢₙ or the voltage of ‘Vₚᵤₗₗ₋ₒᵤₜ’ is not applied, the bit line 20, the write word line 30, and the read word line 40 can be set to be grounded.

Therefore, the memory device according to the second embodiment can write and read the information corresponding to one bit of ‘0’ or ‘1’ by applying a predetermined level of voltage to the bit line 20 and the write word line 30 so that the contact part 100 electrically connected to the bit line 20 can be brought into contact with or be separated from the trap site 80 above the write word line 30.

Then, the flip electrode 50 can be prevented from being easily deformed by an external force if the contact part 100 makes contact with or remains separated from the trap site 80. For example, even if the substrate 10 is bent upward and downward, with the contact part 100 making contact with the write word line 30, the contact part 100 just slides to the right or left about the trench 90 but maintains the contact state with the write word line 30. Further, even when the contact part 100 is separated from the trap site 80, the contact part 100 just become close to or far away from the trap site 80 about the trench 90, but maintains the separated state of the contact part 100 from the trap site 80.

Therefore, since the memory device according to the second embodiment includes a plurality of contact parts 100 making contact with or separated from a plurality of trap sites 80 and separated about the trench 90, it can continuously maintain the state in which the contact part 100 makes contact with or is separated from the trap site 80 even when the substrate 10 is bent. Accordingly, the spatial restrictions can be reduced and damage due to an impact applied from the exterior can be minimized, thereby improving or maximizing the productivity.

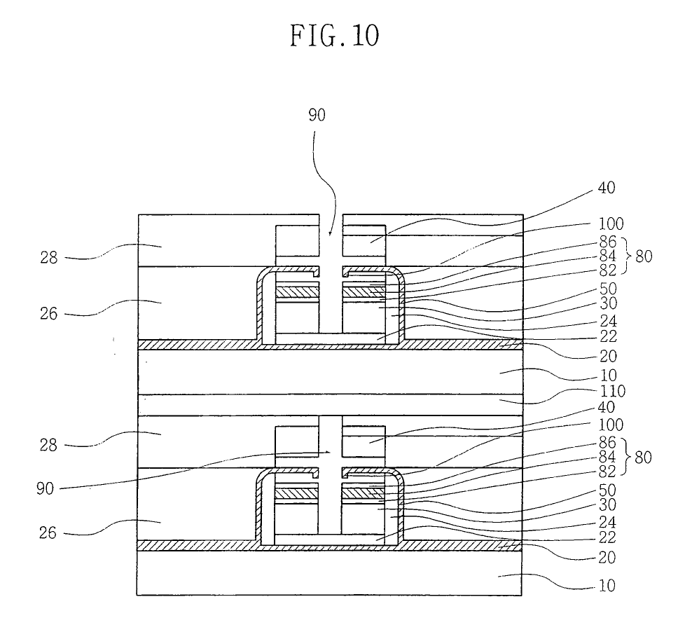

FIG. 10 is a cross-sectional view illustrating a stack structure of the memory device of FIG. 7. In the stack structure, each of a plurality of memory devices includes the contact part 100 protruding in the direction of the write word line from the distal end of the flip electrode 50 inserted between the write word line 30 and the read word line 40, insulated from and disposed above the bit line 20, formed in one direction and crossing the bit line 20 perpendicularly, and configured to contact the trap site 80, with the flip electrode 50 being bent, without supplying charges from outside. Here, the memory devices, each having a plurality of write word lines 30 and a plurality of read word lines 40 above the bit line 20 are formed, with a fourth interlayer insulating layer 110 being interposed therebetween. The fourth interlayer insulating layer 110 covers an upper portion of the trench 90 exposing the first sacrificial layer 60 and the second sacrificial layer 70 removed to form the vacant space between the read word line 40 and the write word line 30.

Although not illustrated, the bit lines 20 in the plurality of memory devices can be alternately formed. Further, at least one switching device, such as a transistor controlling a voltage applied to the memory device, can be formed at the outer periphery of the memory device. Furthermore, various devices such as an MOS transistor, a capacitor, and a resistance can be formed at a portion adjacent to the nonvolatile memory device.

Hereinafter, an embodiment of a method for manufacturing the memory device according to a second embodiment will be described.

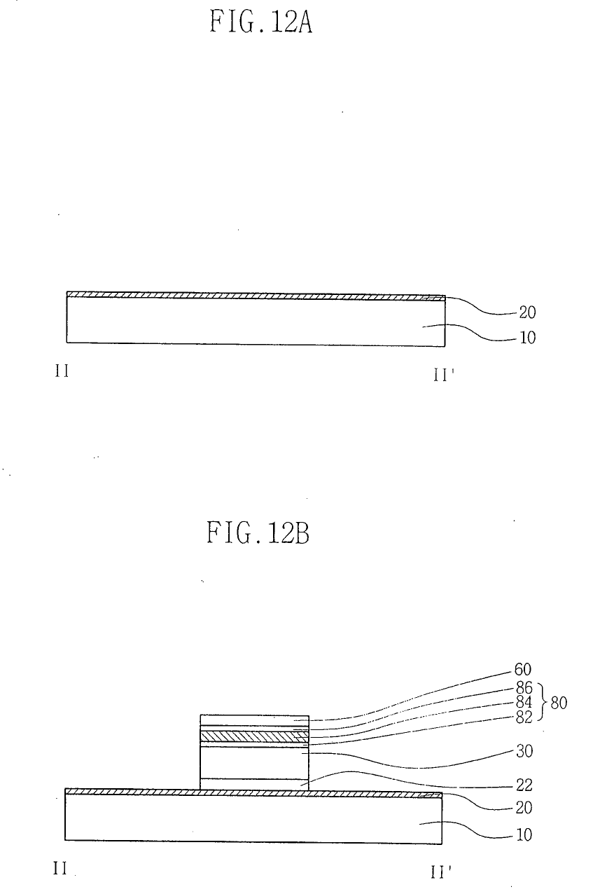

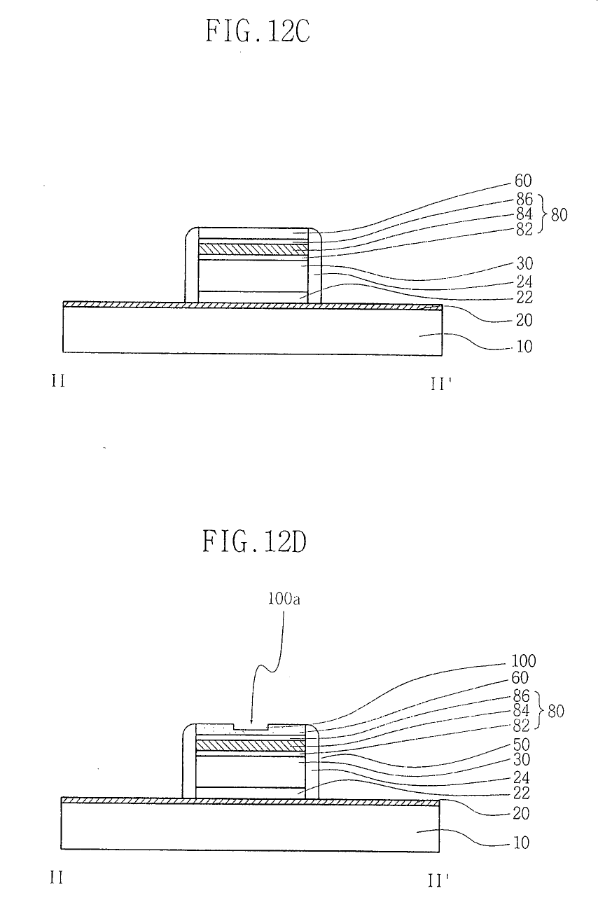

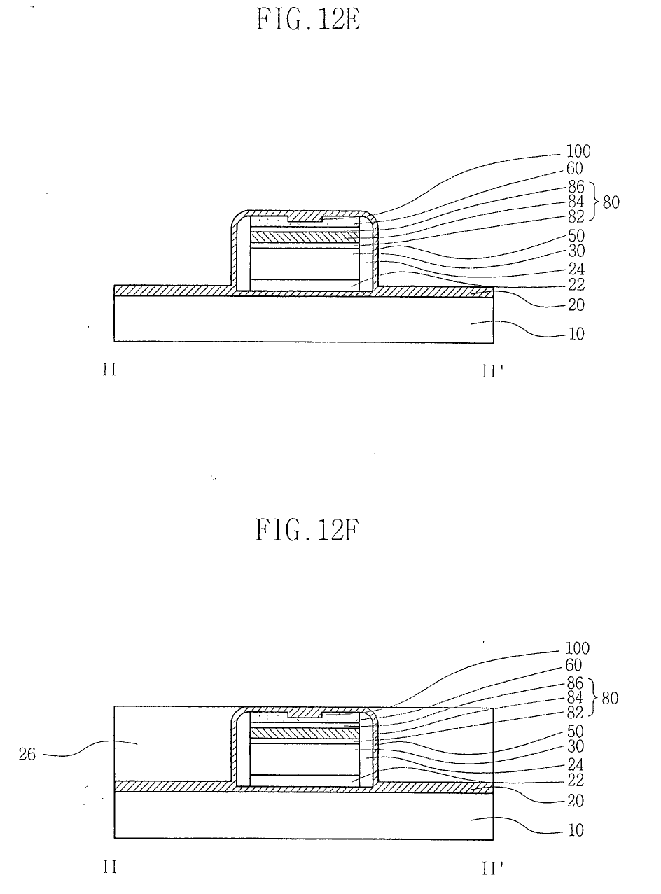

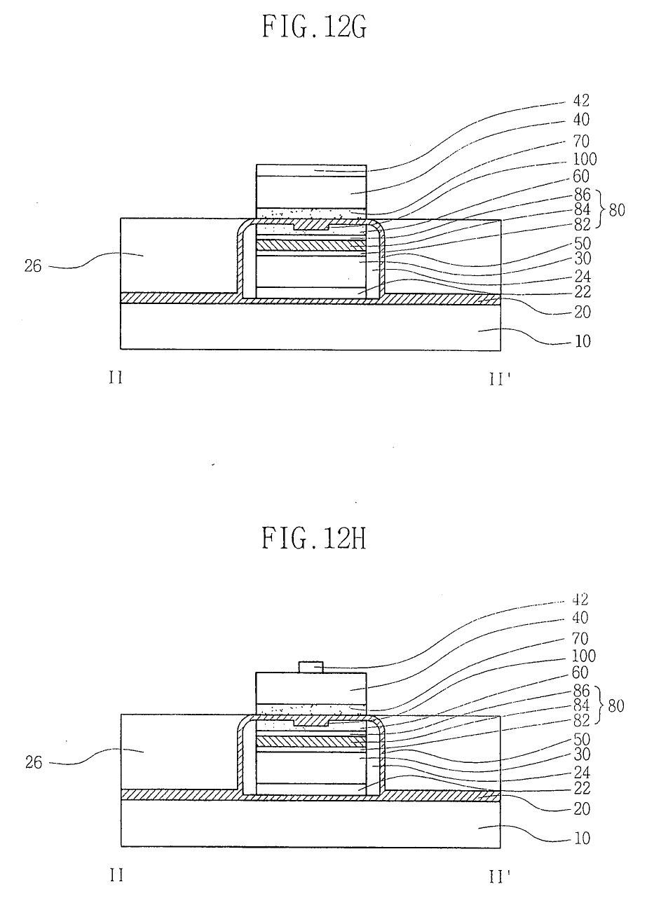

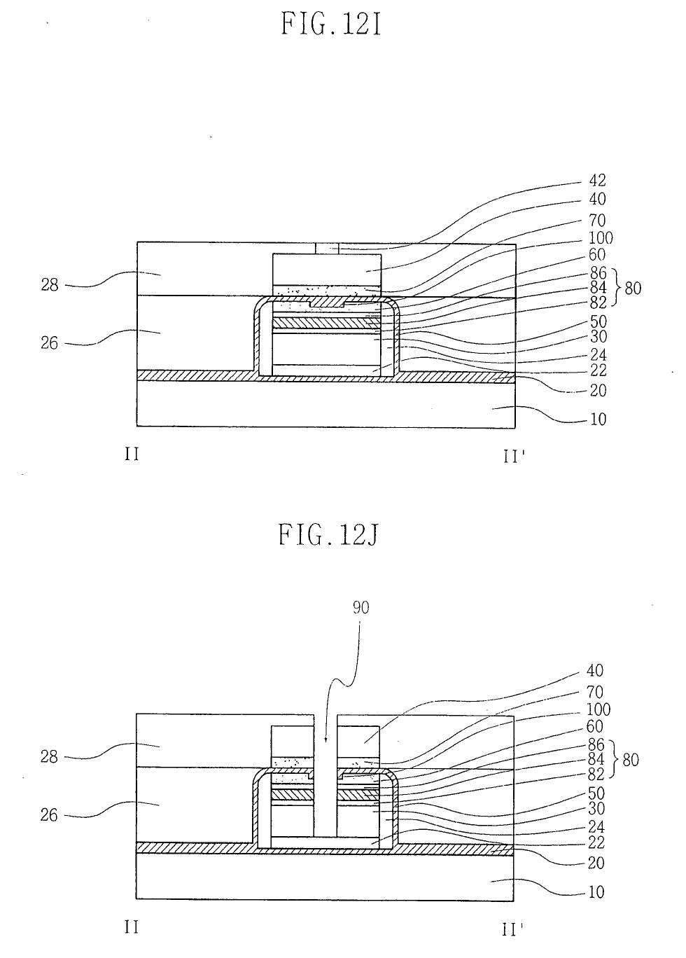

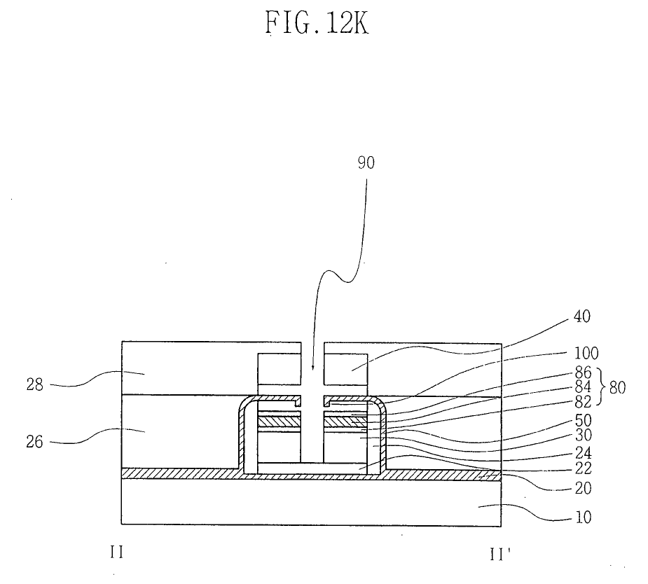

FIGS. 11A to 12K are perspective views and cross-sectional views for explaining a method for manufacturing the memory device of FIGS. 7 and 8. Here, the cross-sectional views of FIGS. 12A to 12K are obtained by cutting away the perspective views of FIGS. 11A to 11K and are sequentially illustrated.

As illustrated in FIGS. 11A and 12A, the bit line 20 having a predetermined thickness is formed on the substrate 10. Here, a plurality of bit lines 20 is formed in parallel to each other in one direction on the substrate. For example, the bit line 20 includes a conductive metal layer, such as gold, silver, copper, aluminum, tungsten, tungsten silicide, titanium, titanium nitride, tantalum, and tantalum silicide or a silicon or polysilicon layer doped with conductive impurities which are manufactured by a physical vapor deposition method and a chemical vapor deposition method. Although not illustrated, the bit line 20 can be formed by anisotropically etching the conductive metal layer or the polysilicon layer by a dry etching method using a photoresist pattern or a first hard mask layer shielding the conductive layer or the polysilicon layer to have a predetermined line width, as an etch mask layer. For example, the reaction gas used in the dry etching method of the conductive metal layer or the polysilicon layer can include a strong acid gas obtained by mixing sulfuric acid and nitric acid. The bit line 20 can have a thickness of approximately 500 Å and a line width of approximately 30 Å to 500 Å.

As illustrated in FIGS. 11B and 12B, the first interlayer insulating layer 22, the write word line 30, the trap site 80, and the first sacrificial layer 60 each having a predetermined line width are formed in a direction crossing the bit line 20. Here, the first interlayer insulating layer 22, the write word line 30, the trap site 80, and the first sacrificial layer 60 are stacked with predetermined thicknesses. The stack of the first interlayer insulating layer 22, the write word line 30, and the first sacrificial layer 60 is formed by anisotropically etching the stack by a dry etching method using one photoresist pattern formed on the first sacrificial layer 60, as an etch mask layer. For example, the first interlayer insulating layer 22 includes a silicon oxide layer or a silicon nitride layer formed to have a thickness of approximately 200 Å to 850 Å by a chemical vapor deposition method. Then, the first interlayer insulating layer 22 can perform a function of an etch stop layer in a process of forming the trench 90 separating the write word line 30 lengthwise. Further, the write word line 30 includes a conductive metal layer, such as gold, silver, copper, aluminum, tungsten, tungsten silicide, titanium, titanium nitride, tantalum, and tantalum silicide, formed by a physical vapor deposition method or a chemical vapor deposition method to have a thickness of approximately 500 Å. The trap site 80 is formed by a rapid thermal treating method, an atomic layer deposition method, or a chemical vapor deposition method to have a thickness of approximately 30 Å to 200 Å. The trap site 80 has an ‘ONO’ structure of the first silicon oxide layer 82, the silicon nitride layer 84, and the second silicon oxide layer 86. The first sacrificial layer 60 includes a polysilicon layer formed by an atomic layer deposition 15 method or a chemical vapor deposition method to have a thickness of approximately 50 Å to 150 Å. The first sacrificial layer 60, the trap site 80, the write word line 30, and the first interlayer insulating layer 22, respectively, have line widths of approximately 30 Å to 1000 Å. The reaction gas used in the dry etching method to pattern the first sacrificial layer 60, the trap site 80, the write word line 30, and the first interlayer insulating layer 22 can be a group of carbon fluoride gas such as a CxFy gas or a CaHbFc gas. The carbon fluoride gas can include CF₄, CHF₃, C₂F₆, C₄F₈, CH₂F₂, CH₃F, CH₄, C₂H₂, and C₄F₆ or a mixture gas thereof.

As illustrated in FIGS. 11C and 12C, the spacer 24 is formed on the sidewall of the stack including the first interlayer insulating layer 22, the write word line 30, the trap site 80, and the first sacrificial layer 60. Here, the spacer 24 is selectively formed on the sidewall of the stack including the first interlayer insulating layer 22, the write word line 30, the trap site 80, and the first sacrificial layer 60, which has a stepped portion, in order to insulate the flip electrode 50 from the write word line 30. For example, the spacer 24 includes a silicon nitride layer or a polysilicon layer formed by a chemical vapor deposition method. Then, the spacer 24 can be self-aligned on the sidewall of the stack by forming a silicon nitride layer or a polysilicon layer having a uniform thickness on the entire surface of the substrate 10 and by anisotropically etching the silicon nitride layer or the polysilicon layer by a dry etching method having excellent vertical etching characteristics. Here, if the spacer 24 includes a silicon nitride layer, the distance between the sidewall of the write word line 30 and the trap site 80, and the flip electrode 50 can be maintained substantially constant. On the other hand, if the spacer 24 includes a polysilicon layer, it can be removed together with the first sacrificial layer 60 to form a vacant space. When the spacer 24 includes the polysilicon layer, it can be formed by the same process as that of the first sacrificial layer 60 after the first interlayer insulating layer 22, the write word line 30, and the trap site 80 are formed. For example, the spacer 24 can be formed by forming the first interlayer insulating layer 22, the write word line 30, and the trap site 80 crossing the bit line 20 on the bit line 20, forming a polysilicon layer on the entire surface of the substrate 10 on which the first interlayer insulating layer 22, the write word line 30, and the trap site 80 are formed, and patterning the polysilicon layer to surround the sidewalls of the first interlayer insulating layer 22, the write word line 30, and the trap site 80, with the spacer being connected to the first sacrificial layer 60 including the polysilicon layer formed on the first interlayer insulating layer 22, the write word line 30, and the trap site 80.

Although not illustrated, when the bit line 20 is formed, a first hard mask layer formed on the bit line 20 can be removed by the reaction gas used by a dry etching method when the spacer 24 is formed. Therefore, the bit line 20 can be exposed when the spacer 24 is formed.

As shown in FIG. 11D and 12D, the dimple 100a or the groove, which is a recessed portion of a central portion of the first sacrificial layer 60, is formed by removing the first sacrificial layer 60 lengthwise by a predetermined depth at an upper central portion of the trap site 80. For example, the dimple 100a or the groove can be formed by removing the first sacrificial layer 60 by a predetermined depth by a wet etching method or a dry etching method using a photoresist pattern or a second hard mask layer exposing an upper central portion of the first sacrificial layer 60 as an etch mask. Then, with the dimple 100a or the groove, the contact part 100 is formed to be electrically connected to the distal end of the flip electrode 50 formed in a subsequent process and make electrical contact with the write word line 30 under a predetermined condition after the first sacrificial layer 60 is removed. Then, the dimple 100a or the groove has a width greater than that of the trench 90 formed to remove the first sacrificial layer 60 in a subsequent process. Therefore, the dimple 100a or the groove formed by removing the center portion of the first sacrificial layer 60 can reduce the distance between the contact part 100 and the trap site 80 when a vacant space is formed by removing the first sacrificial layer 60 in a subsequent process.

As illustrated in FIGS. 11E and 12E, the flip electrode 50 and the contact part 100 are formed crossing an upper portion of the stack including the first sacrificial layer 60, the trap site 80, the write word line 30, and the first interlayer insulating layer 22 and the dimple 100a or the groove and electrically being connected to the bit line 20 adjacent to the spacer 24 on the side surfaces of the stack. Here, the flip electrode 50 is formed over an upper portion of the stack and about the stack with the bit line 20 formed at a lower portion of the stack, and the flip electrode 50 is electrically connected to the bit line 20 formed at both sides of the stack. The flip electrode 50 has a line width equal to or similar to that of the bit line 20 and is stacked on the bit line 20 while covering the spacers at both sides of the stack. Further, the contact part 100 is formed to fill the interior of the dimple 100a or the groove recessed in the direction of the write word line 30 at the center of the flip electrode 50. Then, the contact part 100 is formed with a thickness greater than that of the flip electrode 50. For example, the flip electrode 50 and the contact part 100 are formed by forming a conductive metal layer, such as titanium and titanium silicide or a carbon nano tube having a predetermined thickness, on the entire surface of the substrate 10 in which the stack and the spacer 24 are formed, by forming a photoresist pattern or a third hard mask layer shielding the conductive metal layer or the carbon nano tube on the bit line 20, and by anisotropically etching the conductive metal layer or the carbon nano tube by a dry etching method using the photoresist pattern or the third hard mask layer as an etch mask. Then, the conductive metal layer is formed by a physical vapor deposition method or a chemical vapor deposition method and the carbon nano tube is formed by an electric discharge method. Further, the third hard mask layer can be removed when the flip electrode 50 is patterned or can be left on the flip electrode 50.

Therefore, in the method for manufacturing the memory device according to the second embodiment of the present invention, the distance between the contact part 100 and the trap site 80 can be reduced to be smaller than the distance between the flip electrode 50 and the trap site 80 by forming the contact part 100 protruding in the direction of the trap site 80 from a central portion of the flip electrode 50 covering upper portions of the first interlayer insulating layer 22, the write word line 30, and the trap site 80 crossing the bit line 20.

As illustrated in FIGS. 11F and 12F, the second interlayer insulating layer 26 having a predetermined thickness is formed on the entire surface of the substrate 10 in which the flip electrode 50 and the contact part 100 are formed and the second interlayer insulating layer 26 is removed and planarized to expose the flip electrode 50 and the contact part 100 on the stack. Here, the second interlayer insulating layer 26 provides a planarized surface so that the second sacrificial layer 70 and the read word line 40 can be formed in a direction parallel to the stack, on the flip electrode 50 and the contact part 100 crossing the upper portion of the stack of the write word line 30 having a portion stepped from the substrate 10, the trap site 80, and the first sacrificial layer 60.

Further, the second interlayer insulating layer 26 functions to separately perform patterning processes of the flip electrode 50 and the contact part 100 under the second interlayer insulating layer 26 and the read word line 40. This is because the flip electrode 50 and the read word line 40 include excellent conductive metal layers and an etch selectivity of almost all the etching solutions or reaction gases used to pattern the conductive metal layer is low. Therefore, the second interlayer insulating layer 26 is inevitably used in a process of separately forming two stacked lines or patterns including a conductive metal layer. For example, the second interlayer insulating layer 26 can include a silicon oxide layer formed by TEOS, USG, and HDP chemical vapor deposition method.

Then, the second interlayer insulating layer 26 is formed on the entire surface of the substrate 10 in which the flip electrode 50 and the third hard mask layer are formed to have a height greater than the flip electrode 50. Further, the second interlayer insulating layer 26 can be planarized by removing the second interlayer insulating layer 26 by a chemical mechanical polishing method to expose the flip electrode 50 and the contact part 100 on the first sacrificial layer 60.

Therefore, in the method for manufacturing the memory device according to the second embodiment, the second sacrificial layer 70 and the read word line 40 can be patterned by forming the second interlayer insulating layer 26 on the entire surface of the substrate 10 in which the flip electrode 50 and the contact part 100 are formed and by planarizing the second interlayer insulating layer 26 so that the flip electrode 50 and the contact part 100 formed on the write word line 30 and the first sacrificial layer 60 are exposed.

As illustrated in FIGS. 11G and 12G, the second sacrificial layer 70 and the read word line 40 are formed in a direction parallel to the first sacrificial layer 60, the trap site 80, and the write word line 30 on the flip electrode 50 and the contact part 100 exposed by the second interlayer insulating layer 26. Here, the second sacrificial layer 70 and the read word line 40 are formed symmetrically with respect to the first sacrificial layer 60, the trap site 80, and the write word line 30 about the flip electrode 50. For example, like the first sacrificial layer 60, the second sacrificial layer 70 can be formed of a polysilicon material by an atomic layer deposition method or a chemical vapor deposition method and has a thickness of approximately 50 Å to 150 Å. Further, the read word line 40 has a thickness of approximately 200 Å and has a line width of approximately 30 Å to 1000 Å.

Then, the second sacrificial layer 70 and the read word line 40 can be formed in the following way. First, the polysilicon layer, the conductive metal layer, and the fourth had mask layer 42 each having a predetermined thickness are stacked on the second interlayer insulating layer 26 by a chemical vapor deposition method. Next, a photoresist pattern shielding the fourth hard mask layer 42 on the first sacrificial layer 60, the write word line 30, and the trap site 80 is formed, and after the fourth hard mask layer 42 is removed by a dry etching method or wet etching method using the photoresist pattern as an etch mask, the photoresist pattern is removed by an ashing process. Finally, the second sacrificial layer 70 and the read word line 40 can be formed with predetermined line widths by anisotropically etching the polysilicon layer and the conductive metal layer by a dry etching method and wet etching method using the fourth hard mask layer 42 as an etch mask.

As illustrated in FIGS. 11H and 12H, the fourth hard mask layer 42 formed on the read word line 40 is reduced and patterned to a predetermined line width. Here, the patterned fourth hard mask layer 42 defines the line width of the trench 90 in a subsequent process. The patterned fourth hard mask layer 42 is formed with a line width smaller than that of the contact part 100. Then, the fourth hard mask layer 42 is anisotropically etched by a dry etching method or wet etching method using a photoresist pattern shielding the lengthwise center of the read word line 40 formed in one direction as an etch mask to reduce the line width. Further, the fourth hard mask layer 42 can be isotropically etched by a dry etching method or wet etching method having excellent etching characteristics in a side surface direction rather than a plan surface direction to reduce the line width. The reaction gas or the etching solution used in an isotropic dry etching method or a wet etching method can selectively etch a side surface of the fourth hard mask layer 42 while flowing in a direction parallel to the substrate 10.

As illustrated in FIGS. 11I and 12I, a third interlayer insulating layer 28 of a predetermined thickness is formed over the entire surface of the substrate with the fourth hard mask layer 42 having a reduced line width and the third interlayer insulating layer 28 is planarized to expose the fourth hard mask layer 42. Here, the third interlayer insulating layer 28 has a thickness greater than those of the second sacrificial layer 70 and the read word line 40. Therefore, if the second sacrificial layer 70 is removed in a subsequent process, the third interlayer insulating layer 28 supports a side surface of the read word line 40 and floats the read word line 40 from the flip electrode 50 and the contact part 100. For example, the third interlayer insulating layer 28 can include a silicon oxide layer formed by a TEOS, USG, or HDP chemical vapor deposition method. Further, the third interlayer insulating layer 28 can be planarized by a chemical mechanical polishing method. Then, if the third interlayer insulating layer 28 is planarized using the read word line 40 as a polishing stop layer, since the read word line 40 including a conductive metal layer can be damaged, the fourth hard mask layer 42 should be used as a polishing stop layer.

As illustrated in FIGS. 11J and 12J, the fourth hard mask layer 42, the read word line 40, the second sacrificial layer 70, the flip electrode 50, the contact part 100, the first sacrificial layer 60, the trap site 80, and the write word line 30 sequentially are anisotropically etched by a dry etching method using the third interlayer insulating layer 28 as an etch mask, thereby forming a trench 90 having a bottom at the first interlayer insulating layer 22. Here, the trench 90 symmetrically separates the read word line 40, the second sacrificial layer 70, the flip electrode 50, the contact part 100, the first sacrificial layer 60, and the write word line 30. The trench 90 can be formed by a dry etching method using a reaction gas having a high etch selectivity with respect to the polysilicon and the conductive metal layer corresponding to the third interlayer insulating layer 28 including a silicon oxide layer and the first interlayer insulating layer 22. For example, the reaction gas used in the dry etching method can be selected from a group of carbon fluoride gases such as a CxFy gas or a CaHbFc gas. The carbon fluoride gas can include CF₄, CHF₃, C₂F₆, C₄F₈, CH₂F₂, CH₃F, CH₄, C₂H₂, and C₄C₆ or a mixture gas thereof. If the width of the trench 90 is reduced, interference can be generated between the write word line 30, the read word line 40, and the contact part 100, which are adjacent to each other. Further, the etching solution or reaction gas etching the first sacrificial layer 60 and the second sacrificial layer 70 through the trench 90 in a subsequent process can not be normally flowed. On the other hand, if the width of the trench 90 becomes wider, the integration of a unit device can be reduced, but the etching solution or the reaction gas etching the first sacrificial layer 60 and the second sacrificial layer 70 can be flowed smoothly. Therefore, the trench 90 symmetrically separates the write word line 30, the contact part 100 and the read word line 40 and has a line width that enables the etching solution or reaction gas removing the first sacrificial layer 60 and the second sacrificial layer 70 to normally flow. For example, the trench 90 can have a line width of approximately 30 Åto 800 Å.

Although not illustrated, if the process of reducing the line width of the fourth hard mask layer 42 is omitted, the fourth hard mask layer 42, the read word line 40, the second sacrificial layer 70, the flip electrode 50, the contact part 100, the first sacrificial layer 60, the trap site 80, and the write word line 30 are anisotropically etched sequentially to form the trench 90 by a dry etching method using a photoresist pattern exposing the third interlayer insulating layer 28 formed at the lengthwise center of the read word line 40 and the write word line 30 as an etch mask.

As illustrated in FIGS. 11K and 12K, a vacant space in which the flip electrode 50 is floated between the write word line 30 and the read word line 40 is formed by removing the first sacrificial layer 60 and the second sacrificial layer 70 exposed by the trench 90. For example, the first sacrificial layer 60 and the second sacrificial layer 70 can be isotropically etched from an exposed surface of the sidewall of the trench 90 to a side surface by a wet etching method or a dry etching method to be removed. The etching solution used in the wet etching method of the first sacrificial layer 60 and the second sacrificial layer 70 formed of a polysilicon material is a mixture solution in which a strong acid, such as nitric acid, hydrofluoric acid, or acetic acid, is mixed with deionized water at a predetermined concentration. The etching solution or the reaction gas used in the wet etching method or the dry etching method can form a vacant space between the read word line 40 and the write word line 30 by removing in a horizontal direction, the first sacrificial layer 60 and the second sacrificial layer 70 exposed from a sidewall of the trench 90. If the spacer 24 is composed of a polysilicon material, the spacer 24 can also be etched by the etching solution or reaction gas to be formed as a vacant space. Then, if the distance of the vacant space formed between a side surface of the trap site 80 and the flip electrode 50 by removing the spacer 24 is significantly smaller than the vacant space distance between an upper portion of the trap site 80 and the contact part 100, the contact part does not come into contact with the upper portion of the trap site 80, but the flip electrode 50 can make electrical contact with a side surface of the trap site 80, causing a failure in writing and reading information. Therefore, if the spacer 24 is removed, the distance between the trap site 80 and the contact part 100 becomes greater than the distance between the side surface of the trap site 80 and the flip electrode 50.

Although not illustrated, the interior of the trench 90 can be sealed by forming the fourth interlayer insulating layer 110 covering the upper end of the trench 90. Then, the vacant space in the interior of the trench 90 can be filled with nitrogen or argon in the air and a non-reaction gas or can be set to have a vacuum state to increase the movement speed of the contact part 100. Further, another bit line 20, another write word line 30, another contact part 100, another flip electrode 50, and another read word line 40 can be sequentially formed on the substrate 10 in which the fourth interlayer insulating layer 110 is formed to manufacture a memory device having a multi-layer structure.

Therefore, the method for manufacturing the memory device according to the second embodiment can be used to symmetrically form a plurality of write word lines 30, a plurality of flip electrodes 50, and a plurality read word lines 40 using the trench 90 formed in a crossing direction to the bit line 20 formed on the substrate 10, thereby improving the integration of the memory device.

As mentioned above, the memory device according to aspects of the present invention includes the trench separating the read word line having a vacant space, the trap site, and the write word line to both sides in the lengthwise direction and separating the flip electrode and the contact part electrically connected to the bit line below the write word line, thereby reducing the distances between a plurality of lines having a symmetrical structure about the trench 90, and increasing the integration density of a unit device.

Further, the memory device according to aspects of the present invention includes the contact part protruding in the direction of the write word line from the distal end of the flip electrode bent in the direction of the trap site and the write word line to reduce the bent distance of the flip electrode. Further, since the voltage applied between the contact part, the trap site, and the write word line can be reduced to bring the contact part into electrical contact with the trap site, the power consumption can be reduced.

Further, since the memory device according to aspects of the present invention includes a plurality of contact parts making contact with or separated from a plurality of write word lines and separated about the trench, it can continuously maintain the state in which the contact parts make contact with or are separated from the write word lines even when the substrate is bent. Accordingly, the spatial restrictions can be reduced and damage due to an impact applied from outside can be minimized, thereby improving or maximizing the productivity.

Further, since the memory device according to aspects of the present invention includes the trap site trapping charges applied to the write word line by tunneling the charges and continuing the contact state of the contact part using the trapped charges to reduce consumption of the standby power to be applied to store predetermined information and the predetermined information can be prevented from being lost without charges supplied through the write word line, a nonvolatile memory device can be realized.

While the foregoing has described what are considered to be the best mode and/or other preferred embodiments, it is understood that various modifications can be made therein and that the invention or inventions may be implemented in various forms and embodiments, and that they may be applied in numerous applications, only some of which have been described herein. It is intended by the following claims to claim that which is literally described and all equivalents thereto, including all modifications and variations that fall within the scope of each claim.

What is claimed is:

1. A memory device comprising:
a bit line formed in one direction;
a plurality of word lines provided above the bit line insulated from and crossing the bit line, the word lines being formed in parallel to one another, with a vacant space being formed therebetween having a predetermined interval;
a flip electrode electrically connected to the bit line crossing the word lines, formed over one of the word lines above the bit line so as to pass through the vacant space, and configured to be bent in one direction with respect to the plurality of word lines by electric fields induced between the plurality of word lines; and
a contact part configured to concentrate charges induced by the flip electrode in response to charges applied by the word line between the flip electrode and the bit line, the contacting part protruding from a lower end of the flip electrode to have a predetermined thickness in the direction of the word line to reduce the length by which the flip electrode must be bent to selectively bring the word line and the flip electrode into contact.

2. The memory device according to claim 1, further comprising:
a trench separating the plurality of word lines lengthwise and separating the flip electrode and the contact part to make the plurality of word lines, the plurality of flip electrodes, and the plurality of contact parts symmetrical about the trench.

3. The memory device according to claim 1, further comprising:
a trap site formed on the word line adjacent to the bit line so as to be insulated from the word line and the contact part, the trap site being configured to trap a predetermined charge applied from the word line or external to the device so as to electrostatically fix the contact part moved in the direction of the word line in the interior of the vacant space.

4. A memory device comprising:
a substrate having a flat surface;
a bit line formed on the substrate in one direction;
a first interlayer insulating layer and a first word line stacked in a direction crossing the bit line;
a second word line separated from the first word line by a predetermined interval so as to form a vacant space and formed in a direction parallel to the first word line;
a second interlayer insulating layer and a third interlayer insulating layer formed on the substrate on a side surface of the first word line so as to support a side surface of the second word line by a predetermined height;
a flip electrode electrically connected to the bit line at a portion adjacent to the first word line and passing through the vacant space above the first word line, the flip electrode configured to be bent upward and downward by an electric field induced between the first word line and the second word line; and
a contact part formed to protrude from a lower end in the direction of the first word line by a predetermined thickness to reduce the length by which the flip electrode should be vertically bent to come into contact with the first word line, the contract part being a part where charges induced in the flip electrode in response to charges applied to the first word line are concentrated.

5. The memory device according to claim 4, further comprising:
a first sacrificial layer and a second sacrificial layer stacked to be removed from sidewalls thereof exposed by the trench by an etching solution or a reaction gas to form the vacant space between the first word line and the second word line.

6. The memory device according to claim 5, wherein the first sacrificial layer and the second sacrificial layer respectively comprise polysilicon layers.

7. The memory device according to claim 6, wherein the contact part comprises a conductive metal layer filling in a dimple or a groove formed by recessing a central upper portion of the first sacrificial layer by a predetermined depth in the direction of the first word line.

8. The memory device according to claim 6, further comprising:
a spacer formed between the flip electrode and a side surface of a stack comprising the first interlayer insulating layer, the first word line, and the first sacrificial layer.

9. The memory device according to claim 8, wherein the spacer comprises at least one of a silicon nitride layer and a polysilicon layer.

10. The memory device according to claim 9, wherein when the spacer is formed of a polysilicon layer, the polysilicon layer is removed to form a second vacant space between a sidewall of the first word line and the flip electrode.

11. The memory device according to claim 10, wherein the distance between the first word line and the contact part is smaller than the distance of the second vacant space formed between the sidewall of the first word line and the flip electrode.

12. The memory device according to claim 4, further comprising:
a trench separating the first word line on the first interlayer insulating layer, the flip electrode, the contact part, and the second word line.

13. The memory device according to claim 4, wherein the flip electrode and the contact part respectively comprise titanium, a titanium nitride layer, or a carbon nano tube.

14. The memory device according to claim 4, further comprising:
a trap site formed on the first word line so as to be insulated from the first word line and the contact part, the trap site being configured to trap a predetermined charge applied from the first word line or external to the device so as to electrostatically fix the contact part moved in the direction of the first word line in the interior of the vacant space.

15. The memory device according to claim 14, wherein the trap site has a structure in which a silicon oxide layer, a silicon nitride layer, and a silicon oxide layer are stacked to have a predetermined thickness.

16. A method for manufacturing a memory device comprising:
forming a bit line in one direction on a substrate;
forming a stack comprising a first interlayer insulating layer, a first word line, and a first sacrificial layer in a direction crossing the bit line;
forming a spacer on each longitudinal sidewall of the stack;
forming a dimple by recessing a central upper portion of the first sacrificial layer by a predetermined depth;
forming a flip electrode and a contact part to extend between portions of the bit line adjacent to the spacers to cover the first sacrificial layer with the dimple and to be electrically connected to the bit line;
forming a second interlayer insulating layer covering the entire surfaces of the substrate and the bit line on which the flip electrode and the contact part are formed and exposing the flip electrode and the contact part on the stack;
forming a second sacrificial layer and a second word line in the direction of the stack on the flip electrode and the contact part;
forming a third interlayer insulating layer covering the entire surface of the substrate flat and partially opening an upper portion of the second word line in the lengthwise direction;
forming a trench having a predetermined depth by sequentially removing the second word line exposed by the third interlayer insulating layer, the second sacrificial layer, the flip electrode, the contact part, the first sacrificial layer, and the first word line; and
forming a vacant space between the first word line and the second word line by removing the first sacrificial layer and the second sacrificial layer from the sidewalls thereof exposed by the trench so as to float the flip electrode and the contact part in the vacant space.

17. The method according to claim 16, wherein the stack further includes a trap site comprising a first silicon oxide layer, a silicon nitride layer, and a second silicon oxide layer between the first word line and the first sacrificial layer.

18. The method according to claim 17, wherein the trench is formed so as to separate the trap site into two portions symmetrically divided by the trench.

19. The method according to claim 16, wherein the forming of the third interlayer insulating layer comprises:
reducing the line width of a hard mask layer used to pattern the second sacrificial layer and the second word line;
forming a silicon oxide layer to bury the hard mask layer;
partially removing the silicon oxide layer to planarize the silicon oxide layer until a top surface of the hard mask layer is exposed; and
removing the hard mask layer to expose a central upper portion of the second word line.

20. The method according to claim 16, further comprising:
forming a fourth interlayer insulating layer sealing the interior of the trench by covering an upper end of the trench.
